(19) United States
(12) Patent Application Publication
(10) Pub. No.: US 2011/0025655 A1
(43) Pub. Date: Feb. 3, 2011

(54) OPERATIONAL AMPLIFIER AND SEMICONDUCTOR DEVICE USING THE SAME

(75) Inventors: Kouichi Nishimura, Kanagawa (JP); Atsushi Shimatani, Kanagawa (JP); Hiromichi Ohtsuka, Kanagawa (JP)

Correspondence Address: FOLEY AND LARDNER LLP;SUITE 500, 3000 K STREET NW, WASHINGTON, DC, 20007, US

(73) Assignee: Renesas Electronics Corporation

(21) Appl. No.: 12/847,664

(22) Filed: Jul. 30, 2010

(30) Foreign Application Priority Data
Jul. 31, 2009 (JP) 2009-179770
Jun. 22, 2010 (JP) 2010-141824

(51) Int. Cl. H03F 3/45; G06F 3/038

(52) U.S. Cl. 345/204; 330/252; 330/257

(57) ABSTRACT

An operational amplifier is provide with: a first MOS transistor pair connected to a non-inverting input terminal and an inverting input terminal; an intermediate stage connected to the first MOS transistor pair connected to the first MOS transistor pair; a first output transistor having a drain connected to an output terminal; and a first source follower. The first source follower is inserted between a gate of the first output transistor and a first output node of the intermediate stage.

### INCORPORATION BY REFERENCE

This application claims the benefit of priority based on Japanese Patent Application No. 2009-179770, filed on Jul. 31, 2009, and Japanese Patent Application No. 2010-141824, filed on Jun. 22, 2010, the disclosures of which are incorporated herein by reference.

### BACKGROUND OF THE INVENTION

1. Field of the Invention

The present invention relates to an operational amplifier and a semiconductor device using the same.

2. Description of the Related Art

The operational amplifier is one of typical analog circuits used in various semiconductor integrated circuits. An operational amplifier circuit which can operate in the voltage range from the negative power supply voltage V_{SS} to the positive power supply voltage V_{DD} is particularly referred to as a rail-to-rail amplifier. A voltage follower formed of a rail-to-rail amplifier is used as, for example, an output stage of a display panel driver for driving a liquid crystal display panel and other display panels.

FIG. 1 is a circuit diagram illustrating a typical rail-to-rail amplifier disclosed in Japanese Patent Application Publication No. H06-326529 (and the corresponding U.S. Pat. No. 5,311,145). The operational amplifier shown in FIG. 1 is often described as a reference circuit in textbooks and notable documents on the CMOS analog circuit technology.

The operational amplifier in FIG. 1 can be divided into an input stage 1, an intermediate stage 2 and an output stage 3. The input stage 1 includes PMOS transistors MP₁, MP₂, NMOS transistors MN₁, MN₂ and constant current sources I₁ and I₂. The intermediate stage 2 includes current mirrors 2a, 2b, a floating current source 2c and a constant current source I₃. The current mirror 2a is a so-called folded cascade-type current mirror and operates as an active load. The current mirror 2a includes PMOS transistors MP₃, MP₄, MP₅ and MP₆. Similarly, the current mirror 2b is a folded cascade-type current mirror and operates as an active load. The current mirror 2b includes NMOS transistors MN₃, MN₄, MN₅ and MN₆. The floating current source 2c includes a PMOS transistor MP₇ and an NMOS transistor MN₇. The output stage 3 includes a PMOS transistor MP₈ and an NMOS transistor MN₈. Phase compensating capacitors C₁, C₂ are connected between the intermediate stage 2 and the output stage 3.

The NMOS transistors MN₁ and MN₂ have commonly connected sources and form an N-channel differential pair. The constant current source I₁ is connected between the N-channel differential pair and a negative power supply line. Similarly, the PMOS transistors MP₁, MP₂ have commonly connected sources and form a P-channel receiving differential pair. The constant current source I₂ is connected between the sources of the PMOS transistors MP₁, MP₂ and a positive power supply line.

The gate of the PMOS transistor MP₁ and the gate of the NMOS transistor MN₁ are connected to an inverting input terminal 4 which receives an input voltage In⁻, while the gate of the PMOS transistor MP₂ and the gate of the NMOS transistor MN₂ are connected to a non-inverting input terminal 5 which receives an input voltage In⁺. The drain of the PMOS transistor MP₁ is connected to a connection node N_{C} between the drain of the NMOS transistor MN₃ and the source of the NMOS transistor MN₅ in the intermediate stage 2. The drain of the PMOS transistor MP₂ is connected to a connection node N_{D} between the drain of the NMOS transistor MN₄ and the source of the NMOS transistor MN₆. The drain of the NMOS transistor MN₁ is connected to a connection node N_{A} between the drain of the PMOS transistor MP₃ and the source of the PMOS transistor MP₅. The drain of the NMOS transistor MN₂ is connected to a connection node N_{B} between the drain of the PMOS transistor MP₄ and the source of the PMOS transistor MP₆.

The PMOS transistors MP₃ and MP₄ have commonly-connected sources and commonly-connected gates. The commonly-connected sources of the PMOS transistors MP₃ and MP₄ are connected to a positive power supply line 7 to which the positive power supply voltage V_{DD} is supplied. The drain of the PMOS transistor MP₃ is connected the node N_{A} and the drain of the PMOS transistor MP₄ is connected to the node N_{B}.

The source of the PMOS transistor MP₅ is connected to the node N_{A} and the drain of the PMOS transistor MP₅ is connected to the commonly-connected gates of the PMOS transistors MP₃ and MP₄ and the constant current source I₃. The source of the PMOS transistor MP₆ is connected to the node N_{B} and the drain of the PMOS transistor MP₆ is connected to an output node N_{E} in the intermediate stage 2. A bias voltage BP₁ is supplied to the commonly-connected gates of the PMOS transistors MP₅ and MP₆.

The NMOS transistors MN₃ and MN₄ have commonly-connected sources and commonly-connected gates. The commonly-connected sources of the NMOS transistors MN₃ and MN₄ are connected to a negative power supply line 8 to which the negative power supply voltage V_{SS} is supplied. The drain of the NMOS transistor MN₃ is connected to the node N_{C} and the drain of the NMOS transistor MN₄ is connected to the node N_{D}.

The source of the NMOS transistor MN₅ is connected to the node N_{C} and a drain of the NMOS transistor MN₅ is connected to the commonly connected gates of the NMOS transistors MN₃, MN₄ and the constant current source I₃. The source of the NMOS transistor MN₆ is connected to the node N_{D} and the drain of the NMOS transistor MN₆ is connected to an output node N_{F} in the intermediate stage 2. A bias voltage BN₁ is supplied to the commonly-connected gates of the NMOS transistors MN₅ and MN₆.

The PMOS transistor MP₇ has a gate receiving a bias voltage BP₂, a source connected to the output node N_{E}, a drain connected to the output node N_{F}. The NMOS transistor MN₇ has a gate receiving a bias voltage BN₂, a source connected to the output node N_{F}, and a drain connected to the output node N_{E}. As described above, the PMOS transistor MP₇ and the NMOS transistor MN₇ form the floating current source 2c.

The constant current source I₃ is connected between the drain of the PMOS transistor MP₅ and the drain of the NMOS transistor MN₅. As is the case of the floating current source 2c, the constant current source I₃ may be a floating current source formed of a PMOS transistor and an NMOS transistor, a drain of one of the transistors being connected to a source of the other of the transistors.

The PMOS transistor MP₈ is an output transistor having a source connected to the positive power supply line 7, a gate connected to the output node N_{E} and a drain connected to an output terminal 6. Meanwhile, the NMOS transistor MN₈ is an output transistor having a source connected to the negative power supply line 8, a gate connected to the output node N_{F} and a drain connected to the output terminal 6. An output voltage Vout is outputted from the output terminal 6.

The phase compensating capacitance C₁ is connected between the node N_{B} and the output terminal 6. Meanwhile, the phase compensating capacitance C₂ is connected between the node N_{D} and the output terminal 6.

Operations of the operational amplifier circuit in FIG. 1 will be briefly described below. To achieve a Rail-to-Rail operation, the input stage 1 has a differential stage configuration which includes both of a PMOS transistor differential pair and a NMOS transistor differential pair. This necessitates summing the output signals of the PMOS transistor differential pair and the output signals of the NMOS transistor differential pair. For this reason, the differential stage outputs are connected to the nodes N_{A}, N_{B}, N_{C} and N_{D} of the folded cascade-type current mirrors 2a and 2b. Such connections enable summing the currents of the outputs of the PMOS transistor differential pair and the NMOS transistor differential pair. With such configuration, the NMOS transistor differential pair operates in an input signal range in which the PMOS transistor differential pair does not operate. Conversely, the PMOS transistor differential pair operates in an input signal range in which the NMOS transistor differential pair does not operate. As a result, the input stage 1 operates in the whole voltage range from the negative power supply voltage V_{SS} to the positive power supply voltage V_{DD}.

The inventors of the present invention considers that the power consumption in the output stage 3 can be reduced by supplying an intermediate power supply voltage V_{ML} (in place of the negative power supply voltage V_{SS}) to the source of the NMOS transistor MN₈ in the output stage 3 or an intermediate power supply voltage V_{MH} (in place of the positive power supply voltage V_{DD}) to the source of the PMOS transistor MP₈. Most typically, the intermediate power supply voltages V_{MH} and V_{ML} are set to the half power supply voltage between the positive power supply voltage V_{DD} and the negative power supply voltage V_{SS}, that is, (V_{DD}−V_{SS})/2. FIGS. 2A and 2B illustrate operational amplifiers having such configuration.

Basic operations of the operational amplifiers in FIGS. 2A, 2B are the same as those of the operational amplifier in FIG. 1. The difference is that the output dynamic range is limited, since the intermediate power supply voltage V_{MH} or V_{ML} is supplied to the source of the PMOS transistor MP₈ or the NMOS transistor MN₈ in the output stage 3. In other words, the output dynamic range of the operational amplifier in FIG. 2A is from V_{ML} to V_{DD} in, since the intermediate power supply voltage V_{ML} is supplied to the source of the output NMOS transistor MN₈. It should be noted that the negative power supply voltage V_{SS} is supplied to the back gate of the NMOS transistor MN₈. Similarly, the output dynamic range of the operational amplifier in FIG. 2B is from V_{SS} to V_{MH}, since the intermediate power supply voltage V_{MH} is supplied to the source of the output PMOS transistor MP₈. Here, the positive power supply voltage V_{DD} is supplied to the back gate of the PMOS transistor MP₈. The operational amplifiers in FIGS. 2A and 2B have an advantage of low power consumption, since the output stage 3, in which most power is consumed, is driven with a lower voltage (typically, a half voltage) in the operational amplifiers in FIGS. 2A and 2B than the output stage of the normal operational amplifier. Otter operations are the same as those in the operational amplifier in FIG. 1.

The circuit configurations in FIGS. 1, 2A, and 2B, however, have a difficulty in the design and/or the low voltage operation.

For the operational amplifier in FIG. 1, for example, there is a difficulty in designing the PMOS transistors MP₄, MP₆ and the NMOS transistors MN₄, MN₆ which are cascade-connected in the intermediate stage 2. The sum of the drain-to-source voltages of the PMOS transistors MP₄ and MP₆ of the current mirror 2a, which operates as the active load, is equal to the gate-to-source voltage of the output PMOS transistor MP₈. Similarly, the sum of drain-to-source voltages of the NMOS transistors MN₄ and MN₆ of the current mirror 2b is equal to the gate-to-source voltage of the output NMOS transistor MN₈. That is, the following formulas hold;

V_{GS}(MP8)=V_{DS}(MP4)+V_{DS}(MP6), and (1)

V_{GS}(MN8)=V_{DS}(MN4)+V_{DS}(MN6), (2)

where V_{GS}(MP8) is the gate-to-source voltage of the PMOS transistor MP₈; V_{DS}(MP4) is the drain-to-source voltage of the PMOS transistor MP₄; V_{DS}(MP6) is the drain-to-source voltage of the PMOS transistor MP₆; V_{GS}(MN8) is gate-to-source voltage of the NMOS transistor MN₈; V_{DS}(MN4) is the drain-to-source voltage of the NMOS transistor MN₄; and V_{DS}(MN6) is the drain-to-source voltage of the NMOS transistor MN₆.

Here, the above-mentioned formula needs to be satisfied to operate the PMOS transistors MP₄, MP₆ and the NMOS transistors MN₄ and MN₆ in the pentode region, and this imposes many limitations on design of the transistors. According to circumstances, the PMOS transistors MP₄, MP₆ and the NMOS transistors MN₄, MN₆ cannot be designed to have desired characteristics. The circuit configurations in FIGS. 2A and 2B cause a similar problem.

When a non-zero back gate voltage is applied to the NMOS transistor MN₈ and the PMOS transistor MP₈, which operate as the output transistors, the gate-to-source voltage V_{GS} is greatly influenced by the back gate voltage, and this may hinder the low voltage operation of the circuit configurations in FIGS. 2A and 2B. In detail, a back gate voltage which is equal to the intermediate power supply voltage V_{ML} is applied to the NMOS transistor MN₈ in the circuit configuration in FIG. 2A, since the intermediate power supply voltage V_{ML} (typically, approximately V_{DD}/2) is supplied to the source of the NMOS transistor MN₈. Similarly, since the intermediate power supply voltage V_{MH} (typically, approximately VDD/2) is supplied to the source of the PMOS transistor MP₈, a back gate voltage of a voltage (V_{DD}−V_{MH}) (typically, approximately V_{DD}/2) is applied to the PMOS transistor MP₈. When a non-zero back gate voltage is applied, the gate-to-source voltage V_{GS} is expressed by the following formula (3):

$${V}_{GS} = \sqrt{\frac{2 {I}_{D}}{β}} + {V}_{T} + γ \sqrt{{V}_{B}} , \\ β = \frac{W}{L} μ {C}_{0} , \qquad ( 3 )$$

where W is the gate width; L is the gate length; μ is the mobility; C₀ is the gate dielectric film capacitance per unit area; V_{T} is the threshold voltage; I_{D} is the drain current; γ is the constant determined according to manufacture process (generally, 1.0); and V_{B} is the back gate voltage.

As is understood from the formula (3), the influence of the back gate voltage V_{B} on the gate-to-source voltage V_{GS} is larger than the influence of a threshold voltage V_{T}. For example, given that γ is 1.0 and the back gate voltage V_{B} is 3V, the third term in the formula (3) reaches a voltage of 1.7V and thus the gate-to-source voltage V_{GS} exceeds 3V. When this applies to the operational amplifier in FIG. 2A, the source potential of the NMOS transistor MN₈ is approximately V_{DD}/2, resulting in that the back gate voltage is approximately V_{DD}/2. Consequently, the gate-to-source voltage V_{GS}(MN8) of the NMOS transistor MN₈ is as high as 4V or more.

With respect to the floating current source 2c, the PMOS transistor MP₈ and the NMOS transistor MN₈ in the circuit configuration in FIG. 2A, for example, the following formula (4) holds:

V_{DD}−V_{ML}=V_{SS}(MP8)+V_{DS}(MP⁷)+V_{GS}(MN8). (4)

Since the gate-to-source voltage V_{GS}(MN8) of the NMOS transistor MN₈ is as high as 4V or more, the right side of the formula (4) represents 5V or more. This suggests that the positive power supply voltage V_{DD} of approximately 10V is required when the V_{ML} is approximately V_{DD}/2. In a certain application, the positive power supply voltage V_{DD} needs to be less than 10V and the above-mentioned, requirement cannot be met. This also applies to the circuit configuration in FIG. 2B.

### SUMMARY

In order to address such problem, an operational amplifier of the present invention is provided with a source follower inserted between an intermediate stage and an output stage to thereby achieve signal level shifting. The gate of a MOS transistor within the source follower, which provides a high input impedance, is connected to the output of the intermediate stage, and the source of the MOS transistor, which provides a low output impedance, is connected to the output stage. Although the original objective of a source follower is impedance transformation, the source follower also provides a level shift between the input and output. The present invention makes use of this feature of the source follower to achieve a level shift. The present invention also makes use of the impedance transformation given by the source follower. Depending on the direction of the level shift, the use of the source follower effectively improves the design flexibility of the intermediate stage or achieves a low voltage operation.

In an aspect of the present invention, an operational amplifier is provide with a MOS transistor pair connected to a non-inverting input terminal and an inverting input terminal; an intermediate stage connected to the MOS transistor pair connected to the first MOS transistor pair; a output transistor having a drain connected to an output terminal; and a source follower. The source follower is inserted between a gate of the output transistor and an output node of the intermediate stage.

In one embodiment, the MOS transistor pair is composed of MOS transistors of a first conductivity type and the output transistor is a MOS transistor of a second conductivity type opposite to the first conductivity type. The intermediate stage includes a cascade-type current mirror which includes two cascade-connected MOS transistors of the second conductivity type, the cascade-type current mirror being connected between a power supply line and the output node and connected to the MOS transistor pair. The source follower includes a MOS transistor of the second conductivity type having a gate connected to the output node and a source connected to the gate of the output transistor and a constant current source. In such circuit configuration, the source follower effectively increases the potential difference between the power supply line and the output node of the intermediate stage, improving the design flexibility of the intermediate stage.

In another embodiment, the MOS transistor pair is composed of MOS transistors of a first conductivity type and the output transistor is a MOS transistor of a second conductivity type opposite to the first conductivity type. The intermediate stage includes a current mirror connected between a power supply line and the output node and connected to the MOS transistor pair. The source follower includes a MOS transistor of the first conductivity type having a gate connected to the output node and a source connected to the gate of the output transistor and a constant current source. In such circuit configuration, the source follower effectively decreases the voltage applied across the current mirror (that is, the potential difference between the power supply line and the output node of the intermediate stage), allowing a low voltage operation.

The present invention provides a technique for relieving the difficulty in design or a low voltage operation of an operational amplifier.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram illustrating an exemplary configuration of a conventional operational amplifier;

FIG. 2A is a circuit diagram illustrating an exemplary configuration of an operational amplifier considered by the inventors;

FIG. 2B is a circuit diagram illustrating another configuration of the operational amplifier considered by the inventors;

FIG. 3 is a circuit diagram illustrating an exemplary configuration of an operational amplifier in a first embodiment of the present invention;

FIG. 4A is a circuit diagram illustrating an example of the configuration of a P-channel source follower used in respective embodiments of the present invention;

FIG. 4B is a circuit diagram illustrating an example of the configuration of an N-channel source follower used in respective embodiments of the present invention;

FIG. 5A is a circuit diagram illustrating an exemplary configuration of an operational amplifier in a second embodiment of the present invention;

FIG. 5B is a circuit diagram illustrating another exemplary configuration of the operational amplifier in the second embodiment of the present invention;

FIG. 6A is a circuit diagram illustrating an exemplary configuration of an operational amplifier in a third embodiment of the present invention;

FIG. 6B is a circuit diagram illustrating another exemplary configuration of the operational amplifier in the third embodiment of the present invention;

FIG. 6C is a circuit diagram illustrating still another exemplary configuration of the operational amplifier in the third embodiment of the present invention;

FIG. 6D is a circuit diagram illustrating still another exemplary configuration of the operational amplifier in the third embodiment of the present invention;

FIG. 7 is a circuit diagram illustrating a modified configuration of the operational amplifier in the first embodiment of the present invention;

FIG. 8A is a circuit diagram illustrating a modified configuration of the operational amplifier in the second embodiment of the present invention;

FIG. 8B is a circuit diagram illustrating another modified configuration of the operational amplifier in the second embodiment of the present invention;

FIG. 9A is a circuit diagram illustrating a modified configuration of the operational, amplifier in the third embodiment of the present invention;

FIG. 9B is a circuit diagram illustrating another modified configuration of the operational amplifier in the third embodiment of the present invention;

FIG. 10 shows an example of the configuration of an output amplifier circuit for a data line driver in one embodiment of the present invention;

FIG. 11 is a circuit diagram illustrating a part of the operational amplifier of FIG. 6A;

FIG. 12 is a diagram illustrating an operation of the output NMOS transistor of the operational amplifier in FIG. 6A;

FIG. 13 is a circuit diagram illustrating an exemplary configuration of a semiconductor device in one embodiment of the present invention;

FIG. 14 is a circuit diagram illustrating an example of the configuration of a comparator of FIG. 13; and

FIG. 15 is a circuit diagram illustrating another example of the configuration of the comparator of FIG. 13.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

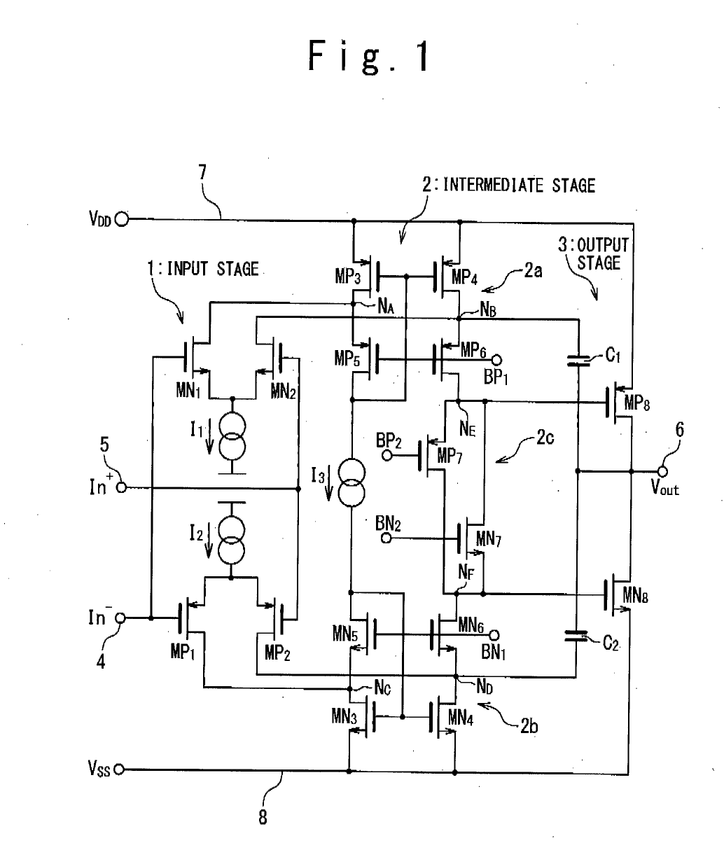

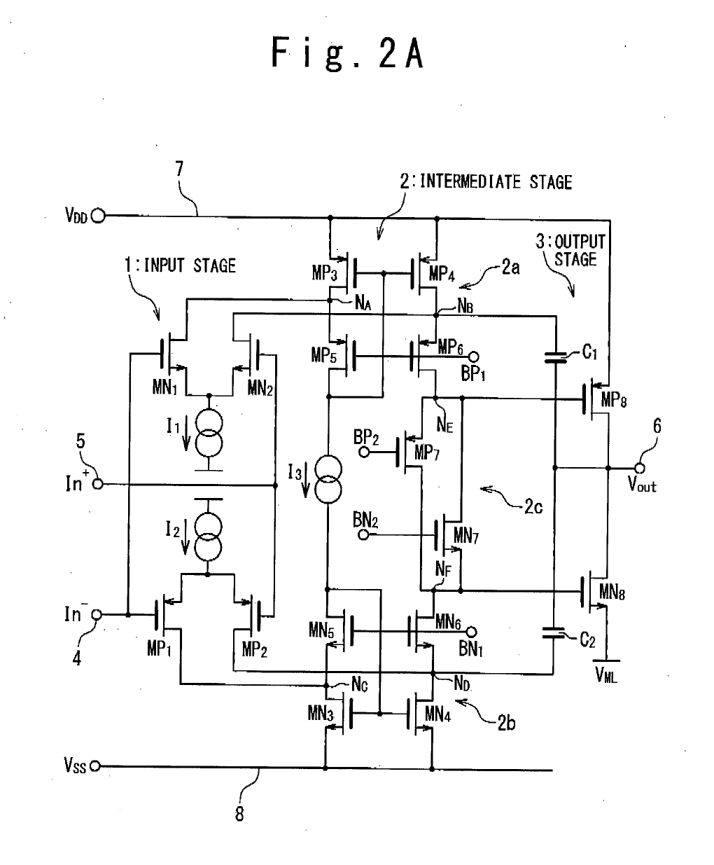

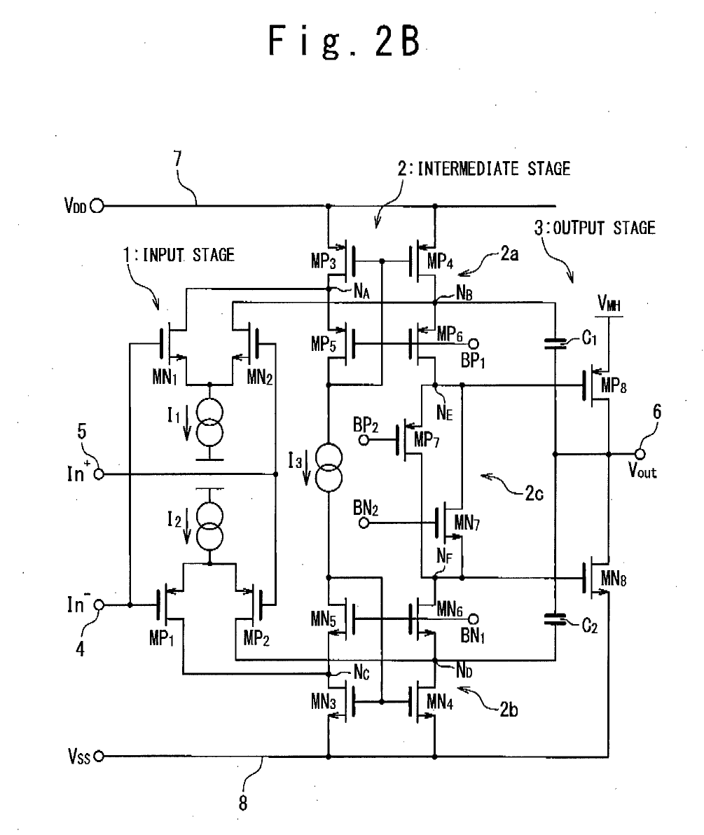

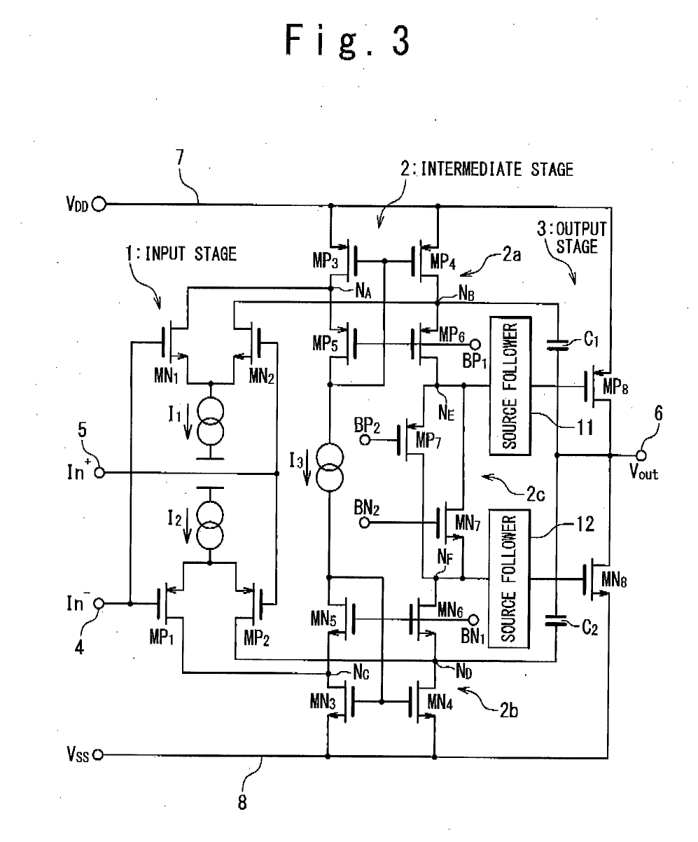

FIG. 3 is a circuit diagram of an operational amplifier in a first embodiment. The operational amplifier in the first embodiment is constituted by inserting source followers 11 and 12 between the gate of the PMOS transistor MP₈ in the output stage 3 and the output node N_{E} in the intermediate stage 2, and between a gate of the NMOS transistor MN₈ in the output stage 3 and the output node N_{F}, in the intermediate stage 2, respectively, in the operational amplifier in FIG. 1.

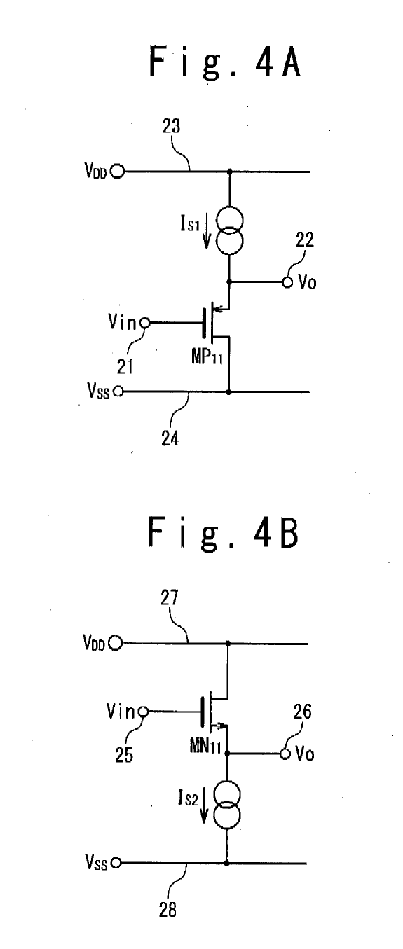

In the first embodiment, a P-channel source follower shown in FIG. 4A is used as the source follower 11 connected to the gate of the PMOS transistor MP₈. The P-channel source follower shown in FIG. 4A includes a constant current source I_{S1} and a PMOS transistor MP₁₁. The PMOS transistor MP₁₁ has a gate connected to the input terminal 21, a source connected to one end of the constant current source I_{S1} and a drain connected to a negative power supply line 24. The other end of the constant current source I_{S1} is connected to a positive power supply line 23. The output terminal 22 is connected to the source of the PMOS transistor MP₁₁. In this embodiment, the input terminal 21 of the P-channel source follower is connected to the output node N_{E} in FIG. 3 and the output terminal 22 is connected to the gate of the PMOS transistor MP₈. In the P-channel source follower shown in FIG. 4A, the voltage level Vin on the input terminal 21 is lower than the voltage level Vo on the output terminal 22 by the threshold voltage V_{TP} of the PMOS transistor MP₁₁. As a result, the voltage level of the output node N_{E} becomes lower than the voltage level of the gate of the PMOS transistor MP₈ by the gate-to-source voltage V_{GS}(MP11) of the PMOS transistor MP₁₁.

On the other hand, an N-channel source follower shown in FIG. 4B is used as the source follower 12 connected to the gate of the NMOS transistor MN₈. The N-channel source follower shown in FIG. 4B includes a constant current source I_{S2} and an NMOS transistor MN₁₁. The NMOS transistor MN11 has a gate connected to the input terminal 25, a source connected to one end of the constant current source I_{S2} and a drain connected to a positive power supply line 27. The other end of the constant current source I_{S2} is connected to a negative power supply line 28. The output terminal 26 is connected to the source of the NMOS transistor MN₁₁. In this embodiment, the input terminal 25 of the N-channel source follower is connected to the output node N_{F} in FIG. 3 and the output terminal 26 is connected to the gate of the NMOS transistor MN₈. In the N-channel source follower in FIG. 4B, the voltage level Vin on the input terminal 25 is higher than the voltage level Vo on the output terminal 26 by the threshold voltage V_{TN} of the NMOS transistor MN₁₁. As a result, the voltage level of the output node N_{F} becomes higher than the voltage level of the gate of the NMOS transistor MN₈ by the gate-to-source voltage V_{GS}(MN11) of the NMOS transistor MN₁₁.

Referring back to FIG. 3, an exemplary operation of the operational amplifier of the first embodiment will be described. The operations of the operational amplifier in FIG. 3 are basically the same as that of the operational amplifier in FIG. 1. The difference is that the two voltage levels of the output nodes N_{E} and N_{F} in the intermediate stage 2 are shifted by the gate-to-source voltage V_{GS}(MP11) of the PMOS transistor MP₁₁ in the source follower 11 and the gate-to-source voltage V_{GS}(MN11) of the NMOS transistor MN₁₁ in the source follower 12, respectively. The gate-to-source voltage V_{GS}(MP11) of the PMOS transistor MP₁₁ and the gate-to-source voltage V_{GS}(MN11) of the NMOS transistor MN₁₁ can be expressed by the above-described formula (3).

In the first embodiment, the source follower 11 operates as a P-channel source follower to decrease the voltage level on the output node N_{E} in the intermediate stage 2 (that is, to increase the voltage level difference from the positive power supply line 7). The source follower 12 operates as an N-channel source follower to increase the voltage level on the output node N_{F} in the intermediate stage 2 (that is, to increase the voltage level difference from the negative power supply line 8). In other words, the drain-to-source voltages of the PMOS transistors MP₄, MP₆ and the NMOS transistors MN₄, MN₆ of the current mirrors 2a, 2b are extended, facilitating the design of the transistors. When the source followers 11 and 12 are not provided, the source-to-drain voltages of the two cascade-connected MOS transistors need to fall below the gate-to-source voltage of one output transistor. By inserting the source followers 11, 12, the source-to-drain voltages of the two MOS transistors fall below a sum of gate-to-source voltages of two MOS transistors, facilitating the design for optimization.

### Second Embodiment

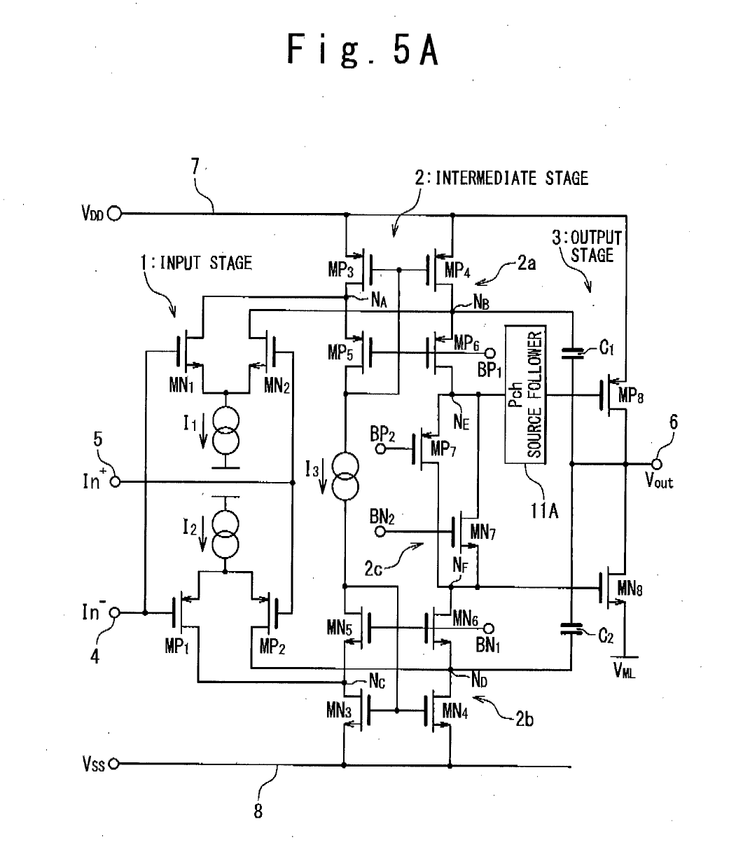

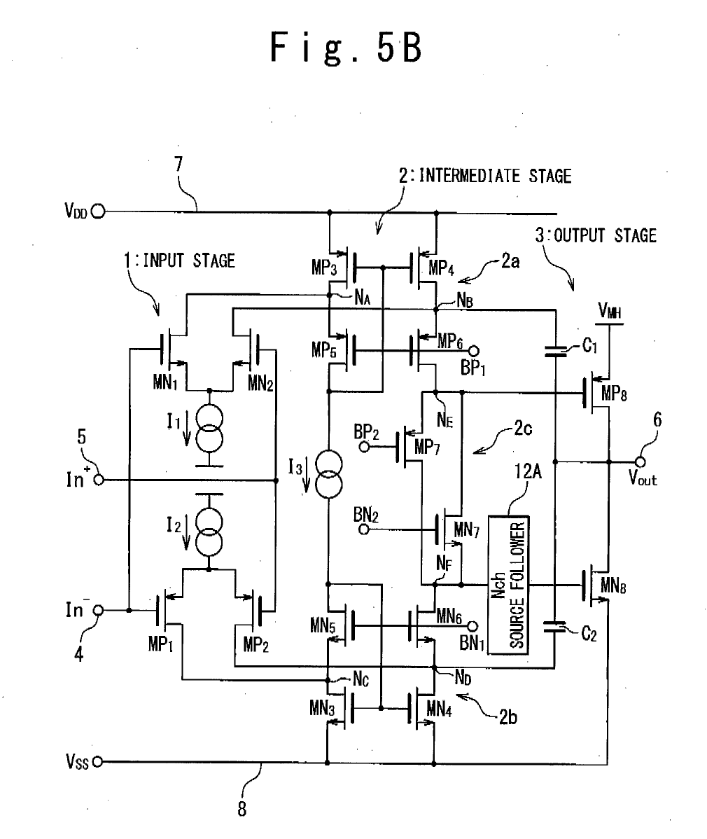

FIGS. 5A and 5B are circuit diagrams illustrating exemplary configurations of operational amplifiers in a second embodiment of the present invention. As described above, in recent years, the inventors have considered a technical concept that the output stage 3 is driven with a voltage which is lower than the source voltage (typically, a half voltage) and the circuit configurations shown in FIGS. 5A, 5B are based on this technical concept.

In the operational amplifier in FIG. 5A, the intermediate power supply voltage V_{ML}, which is a voltage between the negative power supply voltage V_{SS} and the positive power supply voltage V_{DD}, is supplied to the source of the output NMOS transistor MN₈. Most suitably, the intermediate power supply voltage V_{ML} is set to the half of the positive power supply voltage V_{DD}, that is, (V_{DD}−V_{SS})/2. In addition, a source follower 11A is inserted between the gate of the output PMOS transistor MP₈ and the output node N_{E} in the intermediate stage 2. The P-channel source follower in FIG. 4A is used as the source follower 11A. The input terminal 21 of the P-channel source follower is connected to the output node N_{E} in the intermediate stage 2 and the output terminal 22 is connected to the gate of the output PMOS transistor MP₈.

In the operational amplifier in FIG. 5B, the intermediate power supply voltage V_{MH}, which is a voltage between the negative power supply voltage V_{SS} and the positive power supply voltage V_{DD}, is supplied to the source of the output NMOS transistor MN₈. Most suitably, the intermediate power supply voltage V_{MH} is set to a half of the positive power supply voltage V_{DD}, that is, (V_{DD}−V_{SS})/2. In addition, a source follower 12A is inserted between the gate of the output NMOS transistor MN₈ and the output node N_{F} in the intermediate stage 2. The N-channel source follower in FIG. 4B is used as the source follower 12A. The input terminal 25 of the N-channel source follower is connected to the output node N_{F} in the intermediate stage 2 and the output terminal 26 is connected to the gate of the output NMOS transistor MN₈.

Referring to FIGS. 4A and 5A, an exemplary operation of the operational amplifier in FIG. 5A will be described. In the P-channel source follower in FIG. 4A, the following relation holds between the voltage level Vin on the input terminal 21 and the voltage level Vo on the output terminal 22:

Vout=Vin+V_{GS}(MP11), (5)

where V_{GS}(MP11) is the gate-to-source voltage of the PMOS transistor MP₁₁ and is obtained by substituting the current of the constant current source I_{S1} into the drain current I_{D} in the above-described formula (3).

In a case where the P-channel source follower shown in FIG. 4A is used as the source follower 11A in FIG. 5A, the drain voltage V_{D}(MP6) of the PMOS transistor MP₆ of the current mirror 2a in the intermediate stage 2 is expressed by the following formula:

V_{D}(MP6)=V_{DD}−V_{GS}(MP8)−V_{GS}(MP11), (6)

where V_{D}(MP6) is the drain voltage of the PMOS transistor MP₆; V_{GS}(MP8) is the gate-to-source voltage of MP₈; and V_{GS}(MP11) is the gate-to-source voltage of the PMOS transistor MP₁₁ shown in FIG. 4A

In other words, the following formula holds:

$$\begin{matrix}{V}_{DD} - {V}_{D} ( MP 6 ) = {V}_{DS} ( MP 4 ) + {V}_{DS} ( MP 6 ) \\ = {V}_{GS} ( MP 8 ) + {V}_{GS} ( MP 11 ) .\end{matrix} \qquad ( 7 )$$

As is understood from this formula, the circuit configuration in FIG. 5A effectively improves the design flexibility of the PMOS transistors MP4 and MP6, since the sum of the drain-to-source voltages of the two MOS transistors only need to fall below the sum of the gate-to-drain voltages of the two MOS transistors.

The configuration of FIG. 5A provides an improved the design flexibility of the NMOS transistors MN₄ and MN₆ in the current mirror 2b connected to the output NMOS transistor MN₈, since the drain voltage of the NMOS transistor MN₈ is approximately V_{DD}/2. This implies there is no need to insert a source follower between the gate of the NMOS transistor MN₈ and the output node N_{F} in the intermediate stage 2. Therefore, it is deemed that the circuit configuration as shown in FIG. 5A is most preferable.

Subsequently, a description is given of an exemplary operation of the operational amplifier in FIG. 5B, referring to FIGS. 4B and 5B. For the P-channel source follower shown in FIG. 4B, the following relation holds between the voltage level Vin on the input terminal 25 and the voltage level Vo on the output terminal 26:

Vo=Vin−V_{GS}(MN11), (8)

where V_{GS}(MN11) is the gate-to-source voltage of the NMOS transistor MN₁₁ shown in FIG. 4B and is obtained by substituting the current of the constant current source I_{S2} into the drain current I_{D} in the formula (3).

In the case where the N-channel source follower in FIG. 4B is used as the source follower 11A in FIG. 5B, the drain voltage V_{D}(MN6) of the NMOS transistor NM₆ of the current mirror 2b in the intermediate stage 2 is expressed by the following formula:

V_{D}(MN6)=V_{GS}(MN8)+V_{GS}(MN11) (9)

where V_{D}(MN6) is the drain voltage of the NMOS transistor MN₆; V_{GS}(MN8) is the gate-to-source voltage of the NMOS transistor MN₈; and V_{GS}(MN11) is the gate-to-source voltage of the NMOS transistor MN₁₁ in FIG. 4B.

That is, the following formula holds:

$$\begin{matrix}{V}_{D} ( MN 6 ) = {V}_{DS} ( MN 4 ) + {V}_{DS} ( MN 6 ) \\ = {V}_{GS} ( MN 8 ) + {V}_{GS} ( MN 11 ) .\end{matrix} \qquad ( 10 )$$

As is understood from this formula, the circuit configuration in FIG. 5B effectively improvise the design flexibility of the NMOS transistors MN₄ and MN₆, since the sum of the drain-to-source voltages of the two MOS transistors only need to fall below the sum of the gate-to-drain voltages of the two MOS transistors.

With the configuration in FIG. 5B, it can be said that flexibility in design of the PMOS transistors MP₄ and MP₆ is high in the current mirror 2a, since the drain voltage of the PMOS transistor MP₆ is approximately V_{DD}/2. This implies that there is no need to insert a source follower between the gate of the PMOS transistor MP₈ and the output node N_{E} in the intermediate stage 2. Therefore, it is deemed that the circuit configuration as shown in FIG. 5B is most preferable.

### Third Embodiment

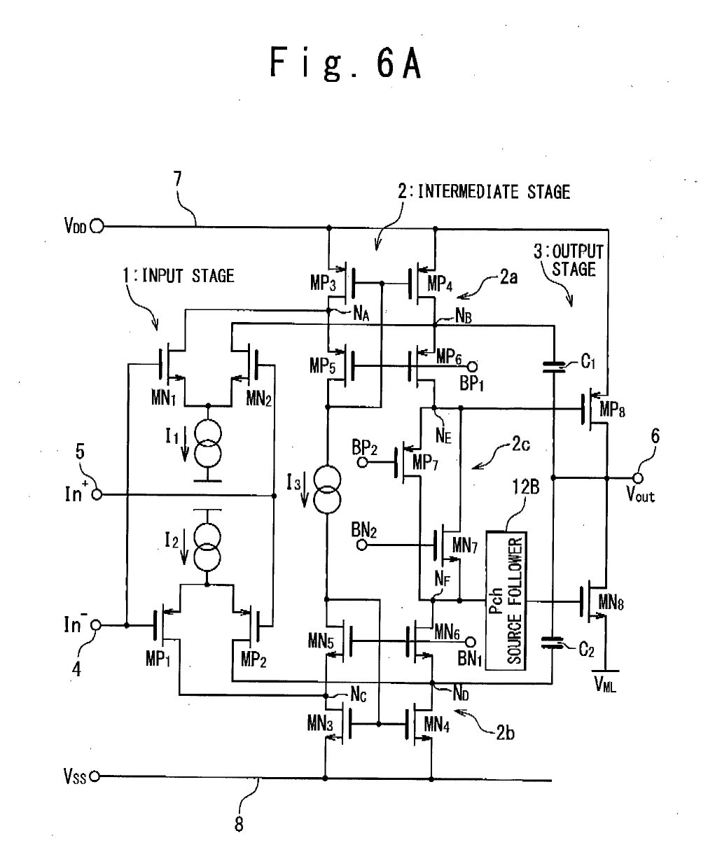

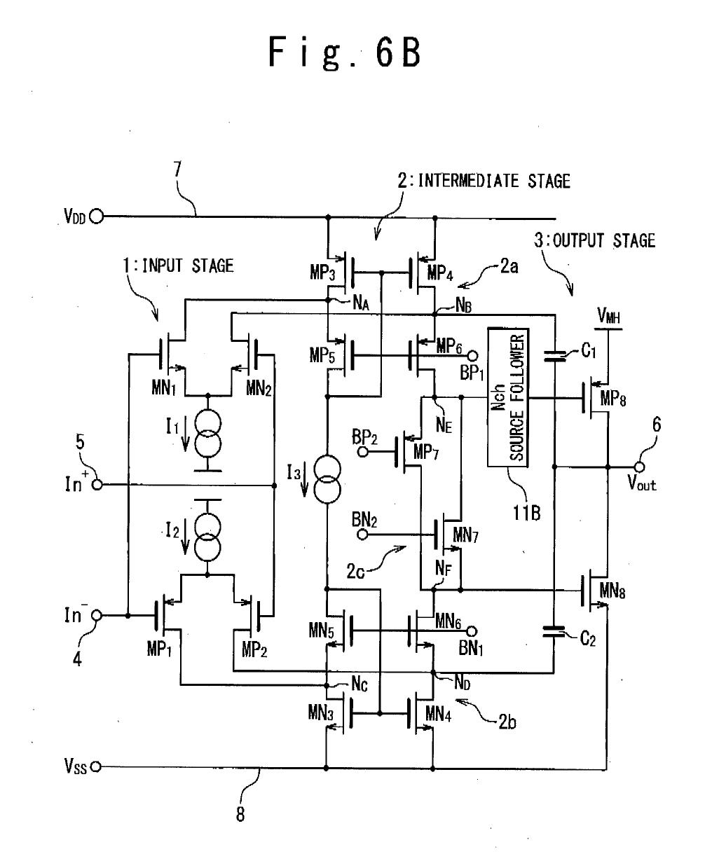

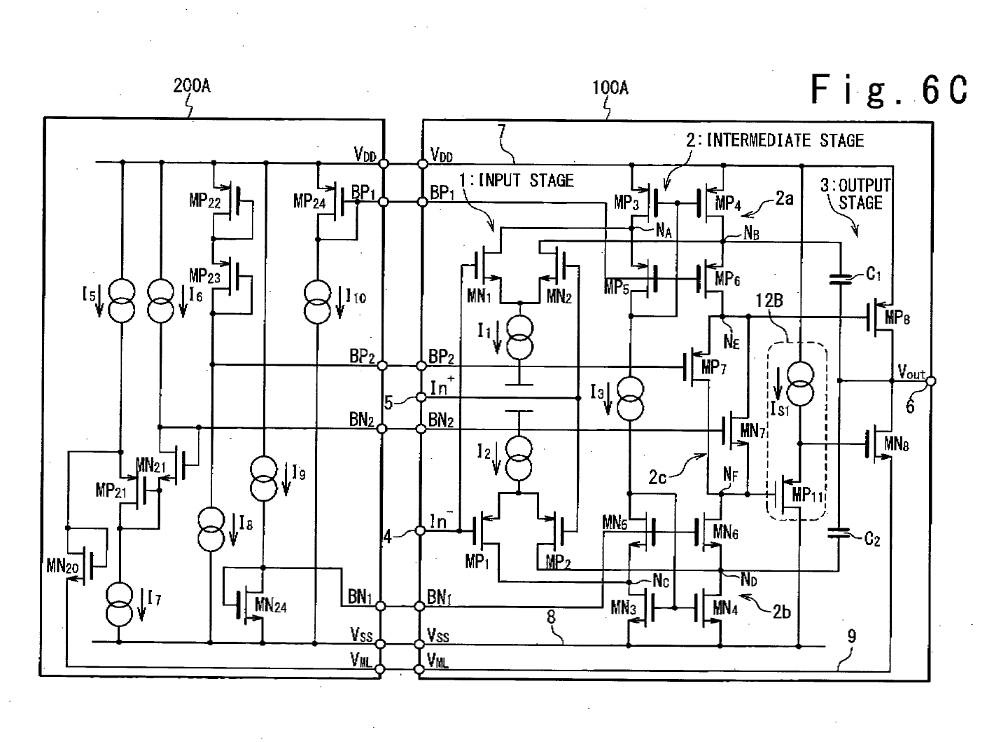

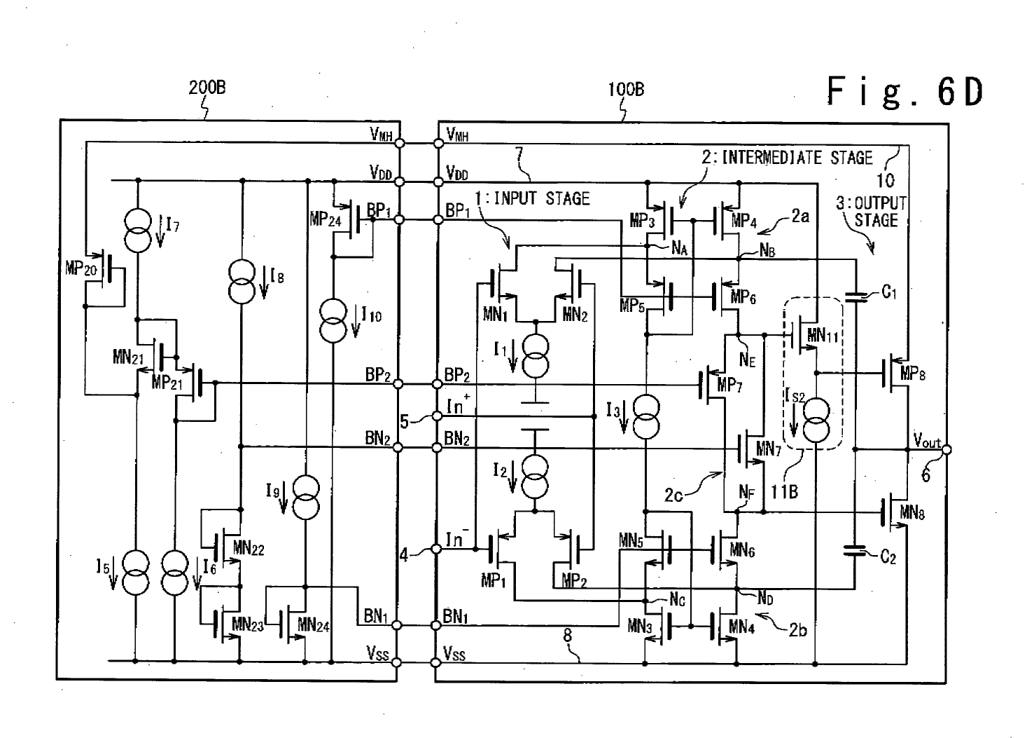

FIGS. 6A and 6B are circuit diagrams illustrating a configuration of an operational amplifier in a third embodiment of the present invention. An exemplary operation in this embodiment will be described. In the same way as the operational amplifiers shown in FIGS. 5A and 5B, the operational amplifiers shown in FIGS. 6A and 6B are configured so as to drive the output stage 3 with a voltage lower than the power supply voltage (typically, the half of the power supply voltage). Nevertheless, the operational amplifiers shown in FIGS. 6A and 6B are structured differently from those shown in FIGS. 5A and 5B in terms of the purpose of the use of source followers, to be adapted to a low voltage operation.

In the operational amplifier in FIG. 6A, the intermediate power supply voltage V_{ML} between the negative power supply voltage V_{SS} and the positive power supply voltage V_{DD} is supplied to the source of the output NMOS transistor MN₈. Most preferably, the intermediate power supply voltage V_{ML} is set to the half of the positive power supply voltage V_{DD}, that is, (V_{DD}−V_{SS})/2. In addition, a source follower 12B is inserted between the gate of the output NMOS transistor MN₈ and the output node N_{F} in the intermediate stage 2. The P-channel source follower in FIG. 4A is used as the source follower 12B. The input terminal 21 of the P-channel source follower is connected to the output node N_{F} in the intermediate stage 2 and the output terminal 22 is connected to the gate of the output NMOS transistor MN₈.

In the operational amplifier in FIG. 6B, the intermediate power supply voltage V_{MH} between the negative power supply voltage V_{SS} and the positive power supply voltage V_{DD} is supplied to the source of the output PMOS transistor MP₈. Most preferably, the intermediate power supply voltage I_{MH} is set to the half of the positive power supply voltage V_{DD}, that is, (V_{DD}−V_{SS})/2. In addition, a source follower 11B is inserted between the gate of the output PMOS transistor MP₈ and the output node N_{E} in the intermediate stage 2. The N-channel source follower in FIG. 4B is used as the source follower 12A. The input terminal 25 of the N-channel source follower is connected to the output node N_{E} of the intermediate stage 2 and the output terminal 26 is connected to the gate of the output PMOS transistor MP₈.

Referring to FIGS. 6A and 4A, an exemplary operation of the operational amplifier in FIG. 6A will be described. In a case where the P-channel source follower in FIG. 4A is used as the source follower 12B in FIG. 6A, the drain voltage V_{D}(MN6) of the NMOS transistor MN₆ of the current mirror 2b in the intermediate stage 2 is expressed by the following formula:

V_{D}(MN6)=V_{ML}+V_{GS}(MN8)−V_{GS}(MP11), (11)

where V_{D}(MN6) is the drain voltage of the NMOS transistor MN₆; V_{GS}(MN8) is the gate-to-source voltage of the NMOS transistor MN₈; and V_{GS}(MP11) is the gate-to-source voltage of the PMOS transistor MP₁₁ in FIG. 4A.

When the P-channel source follower 12B is not provided, the gate-to-source voltages of the NMOS transistors MN₇ and MN₈ are increased, since a non-zero back gate voltage is applied, as described above, Thus, when the positive power supply voltage V_{DD} is relatively low, the required level of the bias voltage BN₂ may exceed the positive power supply voltage V_{DD}, resulting in that the operational amplifier cannot operate. However, as understood from formula (11), the circuit configuration in FIG. 6A allows decreasing the bias voltage BN₂ through decreasing the drain voltage V_{D}(MN6) of the NMOS transistor MN₆ by V_{GS}(MP11), thereby enabling the low voltage operation.

It should be noted, on the other hand, that no source follower is inserted between the gate of the PMOS transistor MP₈ and the output node N_{E} in the intermediate stage 2. This is based on the fact that the difference between the drain voltage V_{D}(MP6) of the PMOS transistor MP₆ and the positive power supply voltage V_{DD} (that is, V_{GS}(MP8)) is originally small, and thus there is no need to bring the drain voltage V_{D}(MP6) of the PMOS transistor MP₆ closer to the positive power supply voltage V_{DD} by inserting a source follower for achieving the low voltage operation.

Next, an exemplary operation of the operational amplifier in FIG. 6B will be described, referring to FIGS. 6B and 4B. In a case where the N-channel source follower in FIG. 4B is used as the source follower 11B in FIG. 6B, the drain voltage V_{D}(MP6) of the PMOS transistor MP₆ of the active load in the intermediate stage 2 is expressed by the following formula:

V_{D}(MP6)=V_{MH}−V_{GS}(MP8)+V_{GS}(MN11), (12)

where V_{D}(MP6) is the drain voltage of the PMOS transistor MP₆; V_{GS}(MP8) is the gate-to-source voltage of the PMOS transistor MP₈; and V_{GS}(MN11) is the gate-to-source voltage of the NMOS transistor MN₁₁ in FIG. 4B.

When the N-channel source follower 11B is not provided, the gate-to-source voltages of the PMOS transistors MP₇ and MP₈ are increased, since a non-zero back gate voltage is applied, as described above. Thus, when the positive power supply voltage V_{DD} is relatively low, the required level of the bias voltage BP₂ may be equal to or less than the negative power supply voltage V_{SS}, resulting in that the operational amplifier cannot operate. As is understood from formula (12), however, the circuit configuration shown in FIG. 6B allows increasing the bias voltage BP₂ through decreasing the drain voltage V_{D}(MP6) of the PMOS transistor MP₆ by V_{GS}(MN11), thereby enabling the low voltage operation.

On the other hand, no source follower is inserted between the gate of the NMOS transistor MN₈ and the output node N_{F} in the intermediate stage 2. This is based on the fact that the difference between the drain voltage V_{D}(MN6) of the NMOS transistor MN₆ and the ground source V_{SS} (that is, V_{GS}(MN8)) is originally small, and thus, there is no need to bring the voltage closer to the negative power supply voltage V_{SS} by inserting a source follower.

FIG. 6C is a circuit diagram illustrating an exemplary configuration of a bias circuit 200A used for supplying bias voltages to the operational amplifier in FIG. 6A. In FIG. 6C, the operational amplifier in FIG. 6A is denoted by the reference numeral 100A. The bias circuit 200A supplies the bias voltages BP₁, BN₁, BP₂ and BN₂ to the operational amplifier 100A.

The bias circuit 200A includes NMOS transistors MN₂₀, MN₂₁, MN₂₄, PMOS transistors MP₂₁ to MP₂₄ and constant current sources I₅ to I₁₀. The NMOS transistors MN₂₀, MN₂₁, the PMOS transistor MP₂₁ and the constant current sources I₅ to I₇ constitute a circuitry for generating the bias voltage BN₂ and this circuitry has a configuration for stabilizing the bias voltages BN₂ against variations in parameters, such as the threshold value V_{T}. More specifically, the source of the NMOS transistors MN₂₀ is connected to an intermediate power supply line 9 and the gate and drain of the NMOS transistors MN₂₀ are commonly connected. Here, the intermediate power supply line 9 is a power line for supplying an intermediate power supply voltage V_{ML} to the operational amplifier 100A and the bias circuit 200A. The source of the PMOS transistors MP21 is connected to the commonly connected drain and gate of the NMOS transistors MN20 and the gate and drain of the PMOS transistors MP21 are commonly connected. The source of the NMOS transistor MN21 is connected to the commonly-connected drain and gate of the PMOS transistors MP21 and the commonly-connected gate and drain of the NMOS transistor MN21 are connected to the terminal for outputting the bias voltage BP2. The constant current sources I₅ to I₇ form a bias current source for supplying bias currents to the NMOS transistors MN₂₀, MN₂₁ and PMOS transistors MP₂₁. In detail, the constant current source I₅ is connected between the positive power supply line 7 and the source of the PMOS transistor MP₂₁ (that is, the commonly-connected drain and gate of the NMOS transistors MN₂₀) and supplies constant bias currents to the PMOS transistor MP₂₁ and the NMOS transistors MN₂₀. The constant current source I₆ is connected between the positive power supply line 7 and the source of the NMOS transistor MN₂₁ and supplies a constant bias current to the NMOS transistor MN₂₁. The constant current source I₅ is connected between the source of the PMOS transistor MP₂₁ and the negative power supply line 8 and draws a constant bias current from the PMOS transistor MP₂₁.

The NMOS transistors MN₂₄, the PMOS transistors MP₂₂ to MP₂₄ and the constant current sources I₈ to I₁₀ constitute a circuitry for generating bias voltages other than the bias voltage BN₂ (the bias voltages BP₁, the bias voltage BN₁ and the bias voltages BP₂). This circuitry has a general configuration.

Next, a description is given of an exemplary operation of the bias circuit 200A in FIG. 6C, in particular, an exemplary operation of generating the bias voltage BN₂. The bias currents flowing through the NMOS transistor MN₂₁, the PMOS transistor MP₂₁ and the NMOS transistor MN₂₀ are determined as follows: First, the bias current I_{DS(MN21)} of the NMOS transistor MN₂₁ is determined by a current supplied from the constant current source I₆, and expressed as follows:

I_{DS(MN21)}=I₆. (13)

The bias current I_{DS(MP21)} of the PMOS transistor MP₂₁ is determined by currents supplied from the constant current sources I₆ and I₇, and expressed as follows:

I_{DS(MP21)}=I₇−I₆. (14)

The bias current I_{DS(MN20)} of the NMOS transistor MN₂₀ is determined by currents supplied from the constant current sources I₅, I₆ and I₇, and expressed as follows:

I_{DS(MN20)}=I₅−I_{DS(MP21)}=I₅−I₇−I₆). (15)

It should be noted that the bias currents flowing through the NMOS transistor MN₂₁, the PMOS transistor MP₂₁ and the NMOS transistor MN₂₀ are determined by the currents supplied from the constant current sources I₅, I₆ and I₇ and are hard to be affected by characteristics of these MOS transistors, respectively.

Further, given that the voltage level of the bias voltage BN₂ is V_{(BN2)}, the following formula (16) applies to the NMOS transistors MN₇, MN₈ and the PMOS transistor MP₁₁ of the operational amplifier 100A:

V_{(BN2)}=V_{ML}+V_{GS(MN8)}−V_{GS(MP11)}+V_{GS(MN7)}, (16)

where V_{GS(MN8)} is the gate-to-source voltage of the NMOS transistor MN₈; V_{GS(MP11)} is the gate-to-source voltage of the PMOS transistor MP₁₁; and V_{GS(MN7)} is the gate-to-source voltage of the NMOS transistor MN₇.

On the other hand, the following formula (17) applies to the NMOS transistor MN₂₀, the PMOS transistor MP₂₁ and the NMOS transistor MN₂₁ of the bias circuit 200A:

V_{(BN2)}=V_{ML}+V_{GS(MN20)}−V_{GS(MP21)}+V_{GS(MN21)}. (17)

It should be noted that the number of terms relating to the threshold voltage V_{T} (that is, terms relating to the gate-to-source voltage) of the formulas (16) and (17) is the same as each other. This implies that the voltage value V_{(BN2)} of the bias voltage BN₂ is hard to be affected by variations in the threshold voltage V_{T}. This advantage results from the configuration in which the equal number of NMOS transistors and PMOS transistors are involved between the bias source line for supplying the bias voltage BN₂ and the intermediate power supply line 9.

Since both the right side of the formula (16) and the right side of the formula (17) are equal to the voltage value V_{(BN2)} of the bias voltage BN₂, the following formula is obtained:

V_{ML}+V_{GS(MN8)}−V_{GS(MP11)}+V_{GS(MN7)}=V_{ML}+V_{GS(MN20)}−V_{GS(MP21)}+V_{GS(MN21)}, (18)

Since the relation between the bias drain current and the gate-to-source voltage of each MOS transistor is represented by the formula (3), the following formula is obtained:

$${V}_{ML} + \sqrt{\frac{2 {I}_{D ( MN 8 )}}{{β}_{( MN 8 )}}} + {V}_{T} + γ \sqrt{{V}_{ML}} - ( \begin{matrix}\sqrt{\frac{2 {I}_{D ( MP 11 )}}{{β}_{( MP 11 )}}} + {V}_{T} + \\ γ \sqrt{{V}_{ML} - {V}_{GS}}\end{matrix} ) + \sqrt{\frac{2 {I}_{D ( MN 7 )}}{{β}_{( MN 7 )}}} + {V}_{T} + γ \sqrt{{V}_{ML}} = {V}_{ML} + \sqrt{\frac{2 {I}_{D ( MN 20 )}}{{β}_{( MN 20 )}}} + {V}_{T} + γ \sqrt{{V}_{ML}} - ( \begin{matrix}\sqrt{\frac{2 {I}_{D ( MP 21 )}}{{β}_{( MP 21 )}}} + {V}_{T} + \\ γ \sqrt{{V}_{ML} - {V}_{GS}}\end{matrix} ) + \sqrt{\frac{2 {I}_{D ( MN 21 )}}{{β}_{( MN 21 )}}} + {V}_{T} + γ \sqrt{{V}_{ML}} . \qquad ( 19 )$$

According to the formula (19), the number of terms related to the threshold voltage V_{T} in the left side is equal to that in the right side, and thus, variations of the threshold voltage V_{T} are cancelled. Further, since the number of terms depending on γ in the left side, which correspond to the back gate voltage effect, is equal to that in the right side, and thus variations in γ are cancelled. The same also applies to the intermediate power supply voltage V_{ML}. The remaining terms are related to the bias drain current I_{(DS)} and β, and these terms can be matched relatively easily by the circuit topology and pattern, resulting in that the effect of variations in the elements is small. Therefore, the bias circuit 200A in FIG. 6C can stably generate the bias voltage BN₂.

FIG. 6D is a circuit diagram illustrating an exemplary configuration of a bias circuit 200B for supplying the bias voltages to the operational amplifier in FIG. 6B. In FIG. 6D, the operational amplifier of FIG. 6B is denoted by the reference numeral 100B. The bias circuit 200B supplies the bias voltages BP₁, BN₁, BP₂ and BN₂ to the operational amplifier 100B. The bias circuit 200B of FIG. 6D is obtained merely by exchanging the NMOS transistors and the PMOS transistors of the bias circuit 200A to each other and replacing the intermediate power supply line 9 for supplying the intermediate power supply voltage V_{MH} with an intermediate power supply line 10 for supplying the intermediate power supply voltage V_{MH}; the operational principles of these bias circuits are the same as each other except that the conductivity types of the respective transistors are inverted between the N-type and P-type. As is the case of the bias circuit 200A in FIG. 6C, the bias circuit 200B in FIG. 6D can generate the stable bias voltage BP₂.

The operational amplifier of the present invention is preferably applied as output amplifiers within a data line driver which drive the data lines of a liquid crystal display panel or other display panels. In this case, the output terminal 6 is connected to the inverting input terminal 4 to constitute a voltage follower and the voltage follower is used as an output amplifier. The operational amplifiers in FIGS. 5A, 6A are used to drive the data lines of the liquid crystal display panel with positive drive voltages and the operational amplifiers in FIGS. 5B, 6B are used to drive the data lines with negative drive voltages. Here, a “positive drive voltage” is referred to as a driving voltage of the positive polarity with respect to the common voltage V_{COM} (the voltage applied to the common electrode of the liquid crystal display panel). When the common voltage V_{COM} is set to V_{DD}/2, the positive drive voltage falls within a range of V_{DD}/2 to V_{DD}. Similarly, a “negative drive voltage” is referred to as a driving voltage of the negative polarity with respect to the common voltage V_{COM}. When the common voltage V_{COM} is set to V_{DD}/2, the negative drive voltage falls within a range of V_{SS} to V_{DD}/2.

However, the circuit configurations shown in FIGS. 3, 5A, 5B, 6A and 6B suffer from deviations in the drive voltages due to the offset voltages thereof. When the operational amplifier of the present invention is used as an output amplifier of a liquid crystal display panel driver, it is preferable that the circuit configuration is modified so as to periodically switch the direction of the offset voltage and to thereby cancel the voltage offset over time.

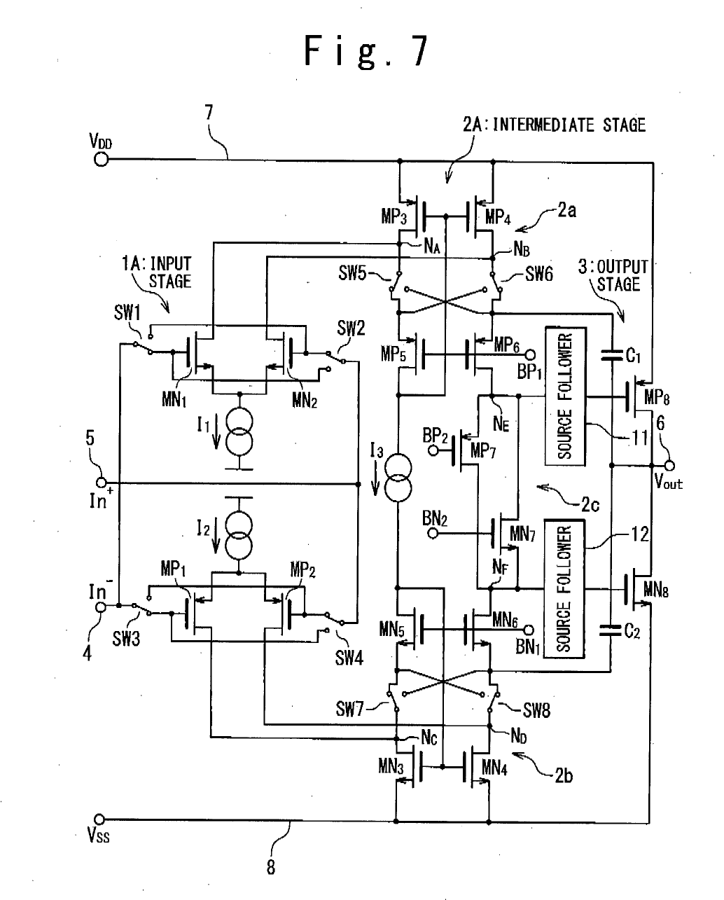

FIGS. 7, 8A, 8B, 9A, and 9B are circuit diagrams illustrating the circuit configurations obtained by modifying the circuit configurations in FIGS. 3, 5A, 5B, 6A, and 6B, respectively, so as to cancel the offset voltage over time. In the circuit configurations in FIGS. 7, 8A, 8B, 9A, and 9B, switches SW1 to SW8 are added.

The switch SW1 is used to switch the connection between the inverting input terminal 4 and gates of the NMOS transistors MN₁ and MN₂ and the switch SW2 is used to switch the connection between the non-inverting input terminal 5 and the gates of the NMOS transistor MN₁ and MN₂. With the switches SW1, SW2, one of the inverting input terminal 4 and the non-inverting input terminal 5 is connected to one of the gates of the NMOS transistors MN₁ and MN₂ and the other of the inverting input terminal 4 and the non-inverting input terminal 5 is connected to the other of the gates of the NMOS transistors MN₁ and MN₂.

Similarly, the switch SW3 is used to switch the connection between the inverting input terminal 4 and gates of the PMOS transistors MP₁ and MP₂ and the switch SW4 is used to switch the connection between the non-inverting input terminal 5 and the gates of the PMOS transistors MP₁ and MP₂. With the switches SW3 and SW4, one of the inverting input terminal 4 and the non-inverting input terminal 5 is connected to the gate of the PMOS transistor MP₁ and the other of the inverting input terminal 4 and the non-inverting input terminal 5 is connected to the gate of the PMOS transistor MP₂.

The switches SW5 and SW6 are used to switch the connections between the drains of the PMOS transistors MP₃, MP₄ and the sources of the PMOS transistors MP₅, MP₆ in the intermediate stage 2. With the switches SW5 and SW6, the drain of one of the PMOS transistors MP₃ and MP₄ is connected to the source of the PMOS transistor MP₅ and the drain of the other of the PMOS transistors MP₃ and MP₄ is connected to the source of the PMOS transistor MP₆.

Furthermore, the switches SW7 and SW8 are used to switch the connections between the drains of the NMOS transistors MN3 and MN4 and the sources of the NMOS transistors MN₅ and MN₆ in the intermediate stage 2. With the switches SW7 and SW8, the drain of one of the NMOS transistors MN₃ and MN₄ is connected to the source of the NMOS transistor MN₅ and the drain of the other of the NMOS transistors MN₃ and MN₄ is connected to the source of the NMOS transistor MN₆.

By switching the above-mentioned switches SW1 to SW8 at appropriate time intervals, the offset voltage can be cancelled over time.

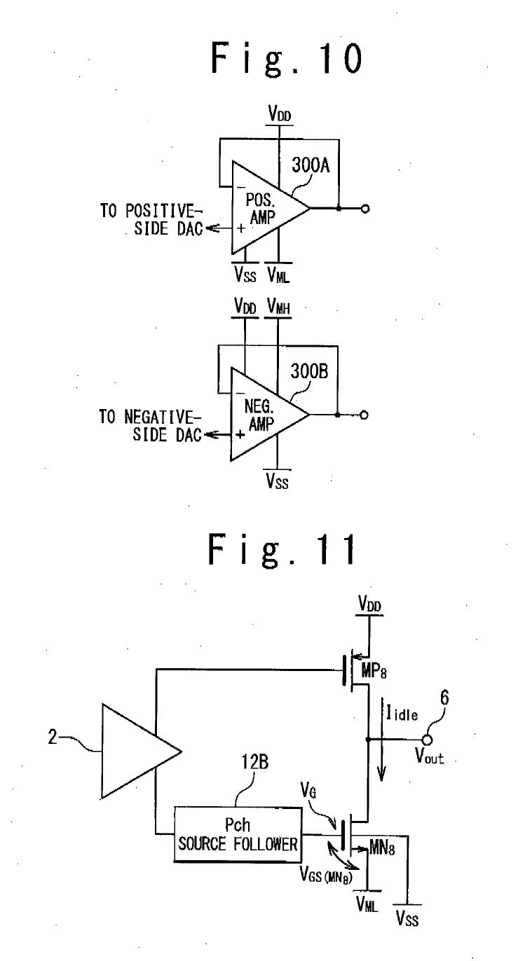

FIG. 10 shows an example of an output amplifier circuit for a data line driver which operates on the positive power supply voltage V_{DD}, the negative power supply voltage V_{SS}, and the intermediate power supply voltages V_{ML} and V_{MH}. The output amplifier circuit includes a positive amplifier 300A for driving a data line of a liquid crystal display panel with a positive drive voltage and a negative amplifier 300B for driving another data line with a negative drive voltage. The positive amplifier 300A is fed with the positive power supply voltage V_{DD}, the negative power supply voltage V_{SS}, and the intermediate power supply voltage V_{ML} and the negative amplifier 300B is fed with the positive power supply voltage V_{DD}, the negative power supply voltage V_{SS}, and the intermediate power supply voltage V_{MH}. Any of the operational amplifiers in FIGS. 5A, 6A, 8A and 9A may be used as the positive amplifier 300A. On the other hand, any of the operational amplifiers in FIGS. 5B, 6B, 8B and 9B may be used as the negative amplifier 300B. The output terminals of the positive amplifier 300A and the negative amplifier 300B are connected to the inverting input terminals thereof and the input signals are supplied to the non-inverting input terminals thereof. This allows the positive amplifier 300A and the negative amplifier 300B to operate as voltage followers. Here, a positive D/A converter is connected to the non-inverting terminal of the positive amplifier 300A so that the grayscale voltage corresponding to pixel data indicating the grayscale level of the pixel to be driven with a positive grayscale voltage is supplied from the positive D/A converter to the non-inverting terminal. Similarly, a negative D/A converter is connected to the non-inverting terminal of the negative amplifier 300B so that the grayscale voltage corresponding to pixel data indicating the grayscale level of the pixel to be driven with a negative gradation voltage is supplied from the negative D/A converter to the non-inverting terminal.

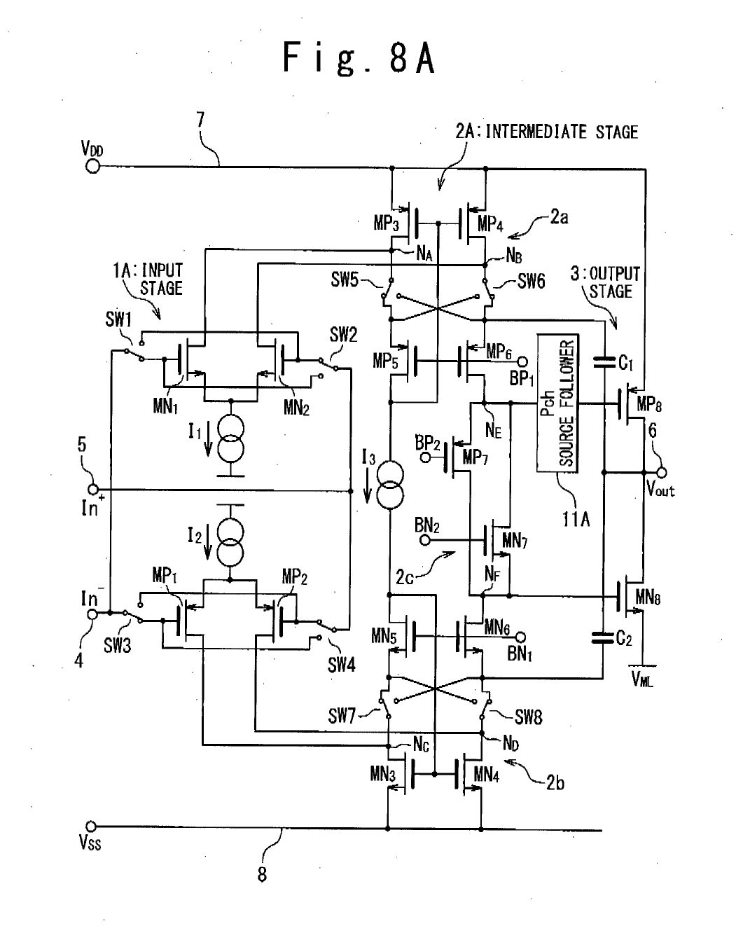

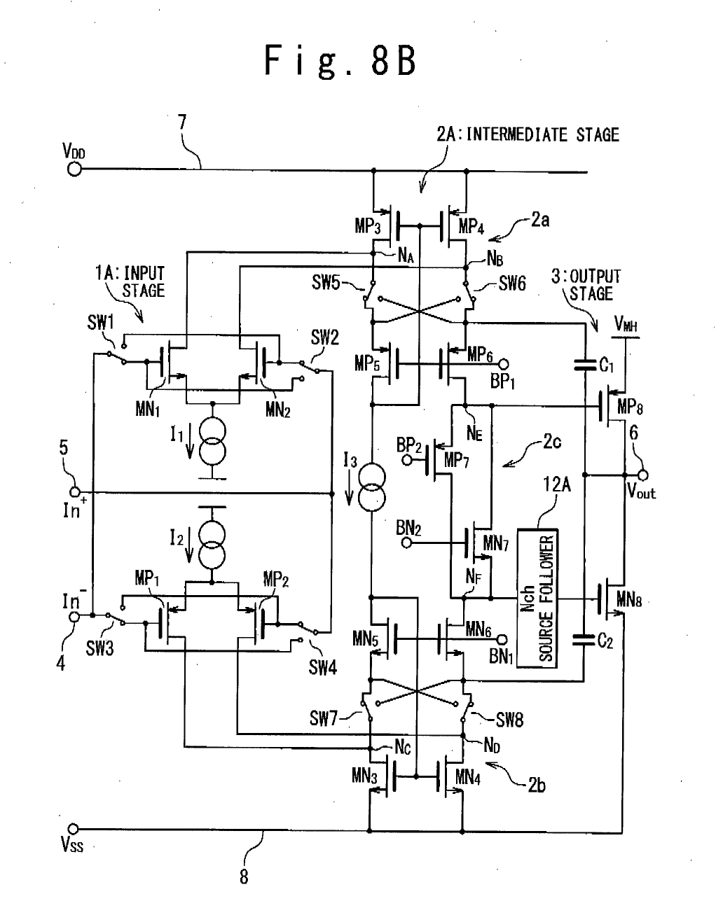

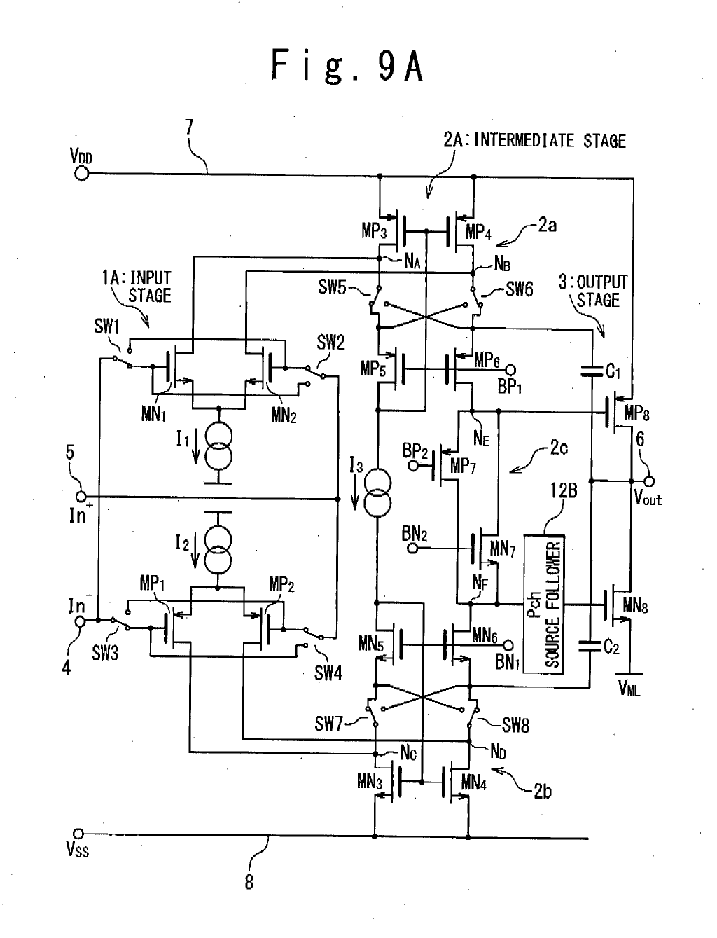

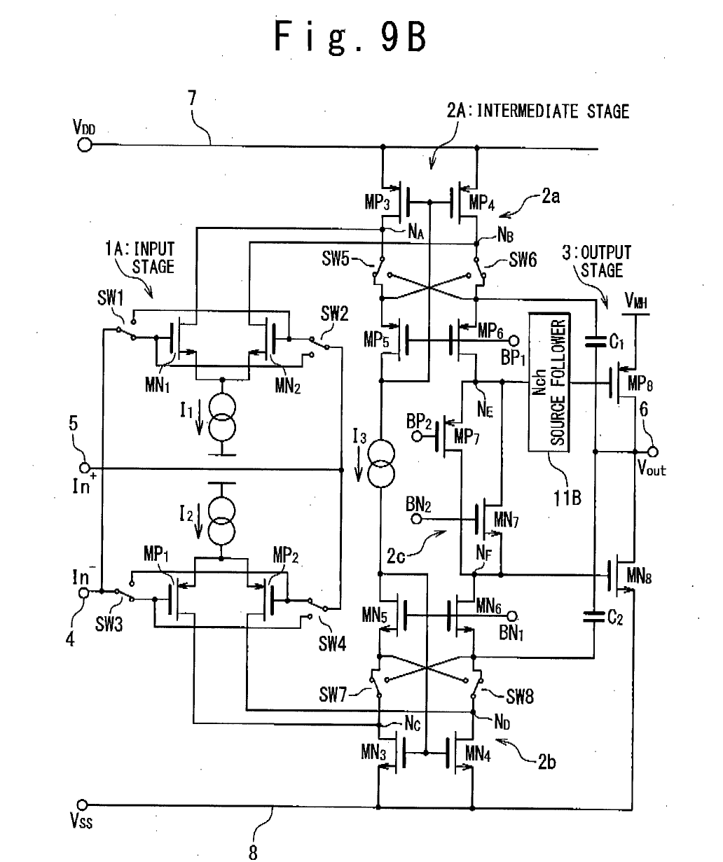

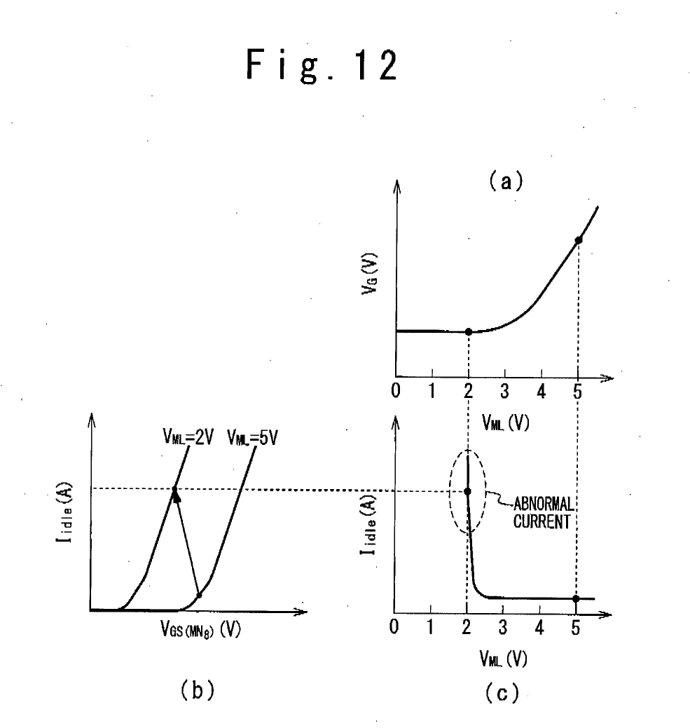

Here, the use of the operational amplifier in FIG. 5A, FIG. 6A, FIG. 8A or FIG. 9A as the positive amplifier 300A may cause a problem that an abnormally large idling current flows through the MOS transistors MP₈ and MN₈ in the output stage 3 under a certain condition. A description is given of this problem in the following. FIG. 11 is a diagram showing a part of the circuit configuration in a case where the operational amplifier 100A in FIG. 6A is used as the positive amplifier 300, and FIG. 12 illustrates an exemplary operation of the MOS transistor MP₈ in the output stage 3. In FIG. 12, the graph (a) of FIG. 12 illustrates the relationship between the intermediate power supply voltage V_{ML} and the gate potential of the NMOS transistor MN₈, the graph (b) illustrates the relationship between the gate-to-source voltage of the NMOS transistor MN₈ and the idling current I_{idle} in the output stage 3 and the graph (c) illustrates the relationship between the intermediate power supply voltage V_{ML} and the idling current I_{idle}, which is derived from the relationship shown in the graphs (a) and (b). Here, the graphs of FIG. 12 each illustrate an example in a case where the intermediate power supply voltage V_{ML} is the half of the source voltage V_{DD}. It should be noted that although a case when the operational amplifier 100A in FIG. 6A is used as the positive amplifier 300A will be described below, the same discussion applies to a case when the intermediate power supply voltage V_{ML} is supplied to the source of the NMOS transistor MN₈ and the back gate of the NMOS transistor MN₈ is grounded (that is, a case when the operational amplifier in any of FIGS. 5A, 8A and 9A is used).

As shown in the graph (a) of FIG. 12, the gate potential V_{G} of the NMOS transistor MN₈ is substantially constant when the intermediate power supply voltage V_{ML} is lower than about 3V and exponentially increased as the intermediate power supply voltage V_{ML} is increased over 3V. As shown in the graph (b) of FIG. 12, the source-to-gate voltage V_{GS(MN8)} of the NMOS transistor MN₈ at which the idling current I_{idle} rises depends on the intermediate power supply voltage V_{ML} and thus, when the intermediate power supply voltage V_{ML} is low, the source-to-gate voltage V_{GS(MN8)} of the NMOS transistor MN₈ with which the idling current I_{idle} rises is also low. As a result, as shown in the graph (c) of FIG. 12, the abnormally-large idling current I_{idle} flows when the intermediate power supply voltage V_{ML} is abnormally decreased.

The same problem also applies to a case when the intermediate power supply voltage V_{MH} is supplied to the source of the PMOS transistor MP₈ of the negative amplifier 300B and the positive power supply voltage V_{DD} is supplied to the back gate of the PMOS transistor MP₈ (that is, a case when the operational amplifier 100B in any of FIGS. 5B, 6B, 8B and 9B is used). Also in this case, when the intermediate power supply voltage V_{MH} is excessively increased, the idling current I_{idle} disadvantageously increases.

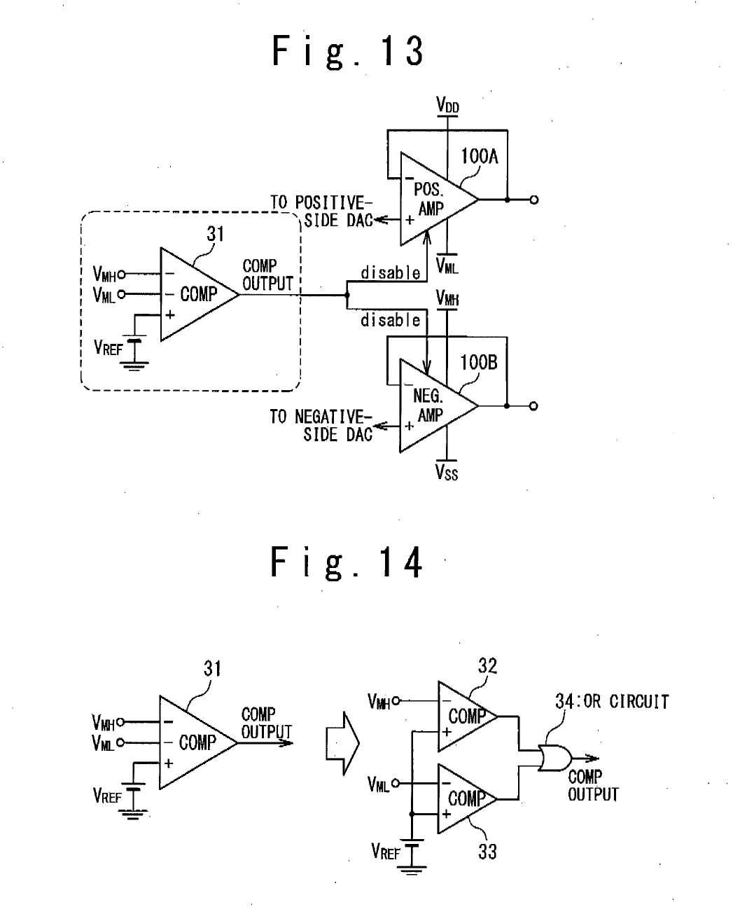

FIGS. 13 to 15 illustrate exemplary configurations of semiconductor devices that solve the problem of the abnormally-large idling current I_{idle}. In general, the intermediate power supply voltages V_{ML} and V_{MH} have the same voltage level, and therefore at least one of the intermediate power supply voltages V_{ML} and V_{MH} should be monitored to avoid the abnormally-increased idle current. In the following, descriptions are given of semiconductor devices in which the intermediate power supply voltages V_{ML} and V_{MH} are both monitored to operate in accordance with the logical sum of the monitoring results.

The semiconductor device in FIG. 13 includes a comparator 31 for controlling the positive amplifier 300A and the negative amplifier 300B. The comparator 31 has two inverting input terminals and one non-inverting input terminal. The intermediate power supply voltage V_{MH} is inputted to one inverting input terminal, the intermediate power supply voltage V_{ML} is inputted to the other inverting input terminal and a reference voltage V_{REF} is inputted to the non-inverting input terminal. In setting the reference voltage V_{REF}, the intermediate power supply voltages V_{ML} and V_{MH} with which the abnormal idling current flows as shown in the graph (c) of FIG. 12 are firstly found, and the reference voltage V_{REF} is set to be higher than the intermediate power supply voltages V_{ML} and V_{MH} with which the abnormal idling current flows. When at least one of the intermediate power supply voltages V_{ML} and V_{MH} is lower than the reference voltage V_{REF}, the output of the comparator 31 is asserted (is set to the High level in this embodiment) and the positive amplifier 300A and the negative amplifier 300B are deactivated in response to the assertion of the output of the comparator 31. To deactivate the positive amplifier 300A and the negative amplifier 300B, for example, the supply of the positive power supply voltage V_{DD} and the intermediate power supply voltages V_{ML} and V_{MH} may be stopped. This allows solving the problem that the idling current I_{idle} is increased when the intermediate power supply voltages V_{ML} or V_{MH} is excessively decreased.

When the intermediate power supply voltage V_{ML} is equal to the intermediate power supply voltage V_{MH}, only either the intermediate power supply voltage V_{ML}, or the intermediate power supply voltage V_{MH} may be inputted to the comparator 31. Also in this case, the positive amplifier 300A and the negative amplifier 300B are deactivated in response to the result of comparison between the inputted intermediate power supply voltage and the reference voltage V_{REF}.

Here, the comparator 31 having the two inverting input terminals may be configured in various ways. For example, as shown in FIG. 14, the comparator 31 may include two two-input comparators 32, 33 and an OR circuit 34. The intermediate power supply voltage V_{MH} is inputted to the inverting input terminal of the comparator 32 and the intermediate power supply voltage V_{ML} is inputted to the inverting input terminal of the comparator 33. The reference voltage V_{REF} is commonly inputted to non-inverting input terminals of the comparators 32 and 33. Output terminals of the comparators 32 and 33 are connected to the input terminal of the OR circuit 34. The output of the OR circuit 34 are used as the output of the comparator 31. When at least one of the intermediate power supply voltages V_{MH} and V_{MH} is lower than the reference voltage V_{REF}, the output of the comparator 31 of such configuration is pulled up to the High level. By deactivating the positive amplifier 300A and the negative amplifier 300B in response to the pull-up of the output of the comparator 31, the abnormally-large idling current can be prevented from flowing.

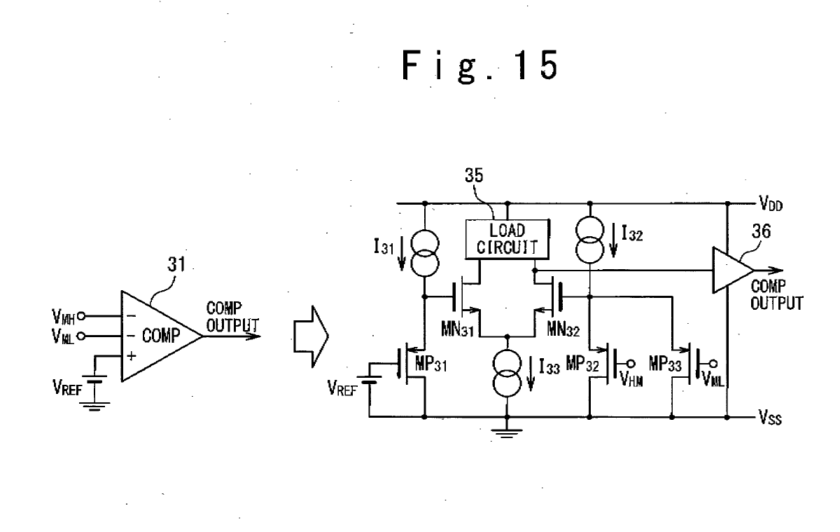

FIG. 15 is a circuit diagram, illustrating an exemplary transistor level configuration of the comparator 31 in FIG. 13. Two PMOS source followers are used as the input differential stage. The first PMOS source follower includes a constant current source I₃₁ and a PMOS transistor MP₃₁. The gate of the PMOS transistor MP₃₁ is used as the inverting input terminal of the comparator 31 and receives the reference voltage V_{REF}. The drain of the PMOS transistor MP₃₁ is connected to the negative power supply line (V_{SS}). The source of the PMOS transistor MP₃₁ is used as the output of the first PMOS source follower and is connected to the gate of an NMOS transistor MN₃₁ in a next differential stage. The constant current source I₃₁ supplies a constant current to the source of the PMOS transistor MP₃₁. The second PMOS source follower comparator 31 includes PMOS transistors MP₃₂, MP₃₃ and a constant current source I₃₂. The gates of the PMOS transistors MP₃₂ and MP₃₃ are used as the inverting input terminals and receive the intermediate power supply voltage V_{MH} and V_{ML}, respectively. The drains of the PMOS transistors MP₃₂ and MP₃₃ are commonly connected to the negative power supply line (V_{SS}). The sources of the PMOS transistors MP₃₂ and MP₃₃ are commonly connected to each other and the commonly-connected sources are connected to the gate of an NMOS transistor MN₃₂ in the next differential stage. The constant current source I₃₂ supplies a constant current to the commonly-connected sources of the PMOS transistors MP₃₂ and MP₃₃. A load circuit 35 is connected to the drains the NMOS transistors MN₃₁, MN₃₂ in the next differential stage and the drain of one of the NMOS transistors MN₃₁, MN₃₂ (the NMOS transistors MN₃₂ in FIG. 15) is connected to the input of an output stage 36. The output of the output stage 36 is used as the output of the comparator 31. In this manner, the same operation as in the circuit in FIG. 14 can be achieved with such simple circuit configuration.

As described above, a source follower is inserted between the intermediate stage and the gate of the output transistor in the operational amplifier of the present invention. The source follower has two types of effects. First, the operational amplifiers of FIGS. 3, 5A, and 5B effectively improve the design flexibility of the transistors by increasing the voltage applied to the cascade-connected active loads (current mirrors 2a, 2b). Second, the operational amplifiers of FIGS. 6A and 6B effectively achieve the lower voltage operation.

Furthermore, the bias circuits in FIGS. 6C, 6D can supply a stable bias voltage to the operational amplifier. In addition, the system configurations in FIGS. 13 to 15 can solve the problem that an abnormal current may flow through the MOS transistors in the output stage in the case where the operational amplifier in FIG. 6A is used as the positive-side amplifier and the operational amplifier in FIG. 6B is used as the negative-side amplifier.

It is apparent that the present invention is not limited to the above embodiments, but may be modified and changed without departing from the scope of the invention.

What is claimed is:

1. An operational amplifier, comprising:
a first MOS transistor pair connected to a non-inverting input terminal and an inverting input terminal;
an intermediate stage connected to said first MOS transistor pair;
a first output transistor having a drain connected to an output terminal; and
a first source follower inserted between a gate of said first output transistor and a first output node of said intermediate stage.

2. The operational amplifier according to claim 1, wherein said first MOS transistor pair is composed of MOS transistors of a first conductivity type,
wherein said first output transistor is a MOS transistor of a second conductivity type which is opposite to said first conductivity type,
wherein said intermediate stage includes a first current mirror provided between a power supply line and said first output node and connected to said first MOS transistor pair, and
wherein said first source follower includes a MOS transistor of said first conductivity type or said second conductivity type, said MOS transistor having gate connected to said first output node and a source connected to the gate of said first output transistor and a first constant current source.

3. The operational amplifier according to claim 2, wherein a conductivity type of said MOS transistor of said first source follower is said first conductivity type.

4. The operational amplifier according to claim 3, further comprising:
a second MOS transistor pair connected to said non-inverting input terminal and said inverting input terminal; and
a second output transistor,
wherein said power supply line is a negative power supply line,
wherein said first MOS transistor pair is a PMOS transistor pair,
wherein said second MOS transistor pair is an NMOS transistor pair,
wherein said first output transistor is an NMOS transistor having a source connected to an intermediate power supply line fed with an intermediate power supply voltage which is lower than a positive power supply voltage and higher than a negative power supply voltage, and a drain connected to said output terminal,
wherein said second output transistor is an PMOS transistor having a gate connected to a second output node of said intermediate stage and a source connected to a positive power supply line,
wherein said intermediate stage further includes:
a second current mirror provided between said positive power supply line and said second output node and connected to said second MOS transistor pair, said second current mirror being composed of PMOS transistors; and
a floating current source connected between said first and second output nodes,
wherein said MOS transistor of said first source follower is a PMOS transistor having a gate connected to said first output node, and a source connected to the gate of said first output transistor and a first constant current source.

5. The operational amplifier according to claim 3, further comprising:
a second MOS transistor pair connected to said non-inverting input terminal and said inverting input terminal; and
a second output transistor,
wherein said power supply line is a positive power supply line,
wherein said first MOS transistor pair is a NMOS transistor pair,
wherein said second MOS transistor pair is an PMOS transistor pair,
wherein said first output transistor is a PMOS transistor having a source connected to an intermediate power supply line fed with an intermediate power supply voltage which is lower than a positive power supply voltage and higher than a negative power supply voltage, and a drain connected to said output terminal,
wherein said second output transistor is an NMOS transistor having a gate connected to a second output node of said intermediate stage, a source connected to a negative power supply line,
wherein said intermediate stage further includes:
a second current mirror provided between said negative power supply line and said second output node and connected to said second MOS transistor pair, said second current mirror being composed of NMOS transistors; and
a floating current source connected between said first and second output nodes,
wherein said MOS transistor of said first source follower is an NMOS transistor having a gate connected to said first output node, and a source connected to the gate of said first output transistor and a first constant current source.

6. The operational amplifier according to claim 4, further comprising:
a first NMOS transistor having a source connected to said intermediate power supply line, a gate and drain of said first NMOS transistor being commonly-connected;
a first PMOS transistor having a source connected to the commonly-connected gate and drain of said first NMOS transistor, a gate and drain of said first PMOS transistor being commonly-connected;
second NMOS transistor having a source connected to the commonly-connected gate and drain of said first PMOS transistor; a gate and drain of said second NMOS transistor being commonly-connected; and
a bias current source supplying bias currents to said first NMOS transistor, said first PMOS transistor and said second NMOS transistor,
wherein said floating current source includes a third NMOS transistor having a drain connected to said first output node and a source connected to said second output node, and
wherein a gate of said third NMOS transistor is connected to the commonly-connected gate and drain of said second NMOS transistor.

7. The operational amplifier according to claim 5, further comprising:
a first PMOS transistor having a source connected to said intermediate power supply line, a gate and drain of said first PMOS transistor being commonly-connected;
a first NMOS transistor having a source connected to the commonly-connected gate and drain of said first PMOS transistor, a gate and drain of said first NMOS transistor being commonly-connected;
a second PMOS transistor having a source connected to the commonly-connected gate and drain of said first NMOS transistor, a gate and drain of said second PMOS transistor being commonly-connected; and
a bias current source supplying bias currents to said first PMOS transistor, said first NMOS transistor and said second PMOS transistor,
wherein said floating current source includes a third PMOS transistor having a source connected to said first output node and a drain connected to said second output node, and
wherein a gate of said third PMOS transistor is connected to the commonly-connected gate and drain of said second PMOS transistor.

8. The operational amplifier according to claim 2, wherein a conductivity type of said MOS transistor of said first source follower is said second conductivity type.

9. The operational amplifier according to claim 8, wherein said power supply line is a positive power supply line,
wherein said first MOS transistor pair is composed of NMOS transistors;
wherein said first output transistor is a PMOS transistor having a source connected to said positive power supply line and a drain connected to said output terminal,
wherein said first current mirror is a cascade-type current mirror including two cascade-connected PMOS transistors connected between said positive power supply line and said first output node,
wherein said MOS transistor of said first source follower is a PMOS transistor having a drain connected to a negative power supply line,
wherein said operational amplifier further comprises;
a second MOS transistor pair connected to said non-inverting input terminal and said inverting input terminal and composed of PMOS transistors;
a second output transistor which is an NMOS transistor having a source connected to said negative power supply line and a drain connected to said output terminal; and
a second source follower inserted between a gate of said second output transistor and a second output node of said intermediate stage,
wherein said intermediate stage further includes:
a second current mirror which is a cascade-type current mirror including two cascade-connected NMOS transistors connected between said negative power supply line and said second output node and connected to said second MOS transistor pair; and
a floating current source connected between said first and second output nodes, and
wherein said second source follower includes an NMOS transistor having a gate connected to said second output node, a source connected to the gate of said second output transistor and a drain connected to said power supply line.

10. The operational amplifier according to claim 8, wherein said power supply line is a positive power supply line,
wherein said first MOS transistor pair is composed of NMOS transistors;
wherein said first output transistor is a PMOS transistor having a source connected to said positive power supply line and a drain connected to said output terminal,
wherein said first current mirror is a cascade-type current mirror including two cascade-connected PMOS transistors connected between said positive power supply line and said first output node,
wherein said MOS transistor of said first source follower is a PMOS transistor,
wherein said operational amplifier further comprises:
a second MOS transistor pair connected to said non-inverting input terminal and said inverting input terminal and composed of PMOS transistors;
a second output transistor which is an NMOS transistor having a source connected to an intermediate power supply line fed with an intermediate power supply voltage which is lower than a positive power supply voltage and higher than a negative power supply voltage, a drain connected to said output terminal and a gate connected to a second output node of said intermediate stage,
wherein said intermediate stage further includes a second current mirror which is a cascade-type current mirror including two cascade-connected NMOS transistors connected between said negative power supply line and said second output node and connected to said second MOS transistor pair.

11. The operational amplifier according to claim 8, wherein said power supply line is a negative power supply line,
wherein said first MOS transistor pair is composed of PMOS transistors;
wherein said first output transistor is a NMOS transistor having a source connected to said negative power supply line and a drain connected to said output terminal,
wherein said first current mirror is a cascade-type current mirror including two cascade-connected NMOS transistors connected between said positive power supply line and said first output node,
wherein said MOS transistor of said first source follower is an NMOS transistor,
wherein said operational amplifier further comprises:
a second MOS transistor pair connected to said non-inverting input terminal and said inverting input terminal and composed of NMOS transistors;
a second output transistor which is an PMOS transistor having a source connected to an intermediate power supply line fed with an intermediate power supply voltage which is lower than a positive power supply voltage and higher than a negative power supply voltage, a drain connected to said output terminal and a gate connected to a second output node of said intermediate stage,
wherein said intermediate stage further includes a second current mirror which is a cascade-type current mirror including two cascade-connected PMOS transistors connected between said positive power supply line and said second output node and connected to said second MOS transistor pair.

12. A semiconductor device, comprising:
an operational amplifier; and
a control circuit,
wherein said operational amplifier includes:
a PMOS transistor pair composed of PMOS transistors and connected to a non-inverting input terminal and an inverting input terminal;
an NMOS transistor pair composed of NMOS transistors and connected to said non-inverting input terminal and said inverting input terminal; and
an intermediate stage connected to said PMOS and NMOS transistor pairs;
an NMOS output transistor having a drain connected to an output terminal and a source connected to an intermediate power supply line fed with an intermediate power supply voltage which is lower than a positive power supply voltage and higher than a negative power supply voltage;
a PMOS output transistor having a drain connected to said output terminal and a source connected to a positive power supply line; and
a first source follower inserted between a gate of said NMOS output transistor and a first output node of said intermediate stage,
wherein a gate of said PMOS output transistor is connected to a second output node of said intermediate stage,
wherein said intermediate stage includes:
a first current mirror provided between a negative power supply line and said first output node and connected to said PMOS transistor pair, and
a second current mirror provided between said positive power supply line and said second output node and connected to said NMOS transistor pair; and
a floating current source connected between said first and second output nodes,
wherein said first source follower includes a PMOS transistor having a gate connected to said first output node and a source connected to the gate of said NMOS output transistor and a first constant current source, and
wherein said control circuit deactivates said operational amplifier in response to said intermediate power supply voltage.

13. The semiconductor device according to claim 12, wherein said control circuit compares said intermediate power supply voltage with a predetermined reference voltage, and deactivates said operational amplifier when said intermediate power supply voltage is lower than said reference voltage.

14. A semiconductor device, comprising:
an operational amplifier; and
a control circuit,
wherein said operational amplifier includes:
a PMOS transistor pair composed of PMOS transistors and connected to a non-inverting input terminal and an inverting input terminal;
an NMOS transistor pair composed of NMOS transistors and connected to said non-inverting input terminal and said inverting input terminal; and
an intermediate stage connected to said PMOS and NMOS transistor pairs;
an NMOS output transistor having a drain connected to an output terminal and a source connected to a negative power supply line;
a PMOS output transistor having a drain connected to said output terminal and a source connected to an intermediate power supply line fed with an intermediate power supply voltage which is lower than a positive power supply voltage and higher than a negative power supply voltage; and
a first source follower inserted between a gate of said PMOS output transistor and a first output node of said intermediate stage,
wherein a gate of said NMOS output transistor is connected to a second output node of said intermediate stage,
wherein said intermediate stage includes:
a first current mirror provided between a negative power supply line and said first output node and connected to said NMOS transistor pair, and
a second current mirror provided between said positive power supply line and said second output node and connected to said PMOS transistor pair; and
a floating current source connected between said first and second output nodes,
wherein said first source follower includes an NMOS transistor having a gate connected to said first output node and a source connected to the gate of said PMOS output transistor and a first constant current source, and
wherein said control circuit deactivates said operational amplifier in response to said intermediate power supply voltage.

15. The semiconductor device according to claim 14, wherein said control circuit compares said intermediate power supply voltage with a predetermined reference voltage, and deactivates said operational amplifier when said intermediate power supply voltage is lower than said reference voltage.

16. A display panel driver, comprising:
an output amplifier driving a data line of a display panel,
wherein said output amplifier includes an operational amplifier, comprising:
a first MOS transistor pair connected to a non-inverting input terminal and an inverting input terminal;
an intermediate stage connected to said first MOS transistor pair connected to said first MOS transistor pair;
a first output transistor having a drain connected to an output terminal; and
a first source follower inserted between a gate of said first output transistor and a first output node of said intermediate stage.
